(19) United States
(12) Patent Application Publication
(10) Pub. No.: US 2006/0258025 A1
(43) Pub. Date: Nov. 16, 2006

(54) Fabrication method of IC inlet, ID tag, ID tag reader and method of reading date thereof

(76) Inventors: Michio Okamoto, Machida (JP); Hisao Yamagata, Gosyogawara (JP); Nobuo Murakami, Ogose (JP); Keizo Kakitani, Kokubunji (JP); Hidehiro Fujiwara, Tachikawa (JP); Takeshi Saitou, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/491,275

(22) Filed: Jul. 24, 2006

Related U.S. Application Data
(63) Continuation of application No. 10/753,454, filed on Jan. 9, 2004.

(30) Foreign Application Priority Data
Jan. 10, 2003 (JP) 2003-004099

(51) Int. Cl. H01L 21/66; G01R 23/16; G01S 3/02; G01V 3/00

(52) U.S. Cl. 438/14; 324/313; 324/76.12; 324/76.14

(57) ABSTRACT

A method accurately inspects whether an IC inlet to be inspected is non-defective or defective in a state in which a large number of IC inlets are formed over an insulating film. The inspection of IC inlets formed over an insulating film is performed by transmitting microwaves to the IC inlets from antennas. To selectively irradiate the microwaves to only one IC inlet to be inspected out of a large number of IC inlets that are formed over the insulating film, a radio-wave absorbing plate is inserted between the insulating film and the antennas, and the microwaves are irradiated to the IC inlet through a slit formed in the radio-wave absorbing plate. The radio-wave absorbing plate is configured such that the slit, which is substantially equal to the IC inlet in size, is formed in a portion of a planar plate that is formed of a radio-wave absorber.

### CROSS-REFERENCE TO RELATED APPLICATIONS

This application is a continuation of U.S. application Ser. No. 10/753,454, filed Jan. 9, 2004, the entire contents of which are incorporated herein by reference.

### BACKGROUND OF THE INVENTION

The present invention relates to a method of fabrication of non-contact type IC inlets, and, more particularly, to a technique which is effective when applied to an inspection of IC inlets during the fabrication thereof.

In Japanese Unexamined Patent Publication No. Hei 10 (1998)-13296 discloses one example of an IC inlet of the type which is used in a non-contact type tag. This IC tag is configured in such a way that an antenna for receiving microwaves is constituted of a lead frame, and a semiconductor chip is mounted on the lead frame by resin sealing.

Japanese Unexamined Patent Publication No. 2001-116784 discloses the structure of a device for measuring the transmission/reception performance of vehicle-mounted small radio wave equipment of the type which is used for a toll road automatic payment collection system. In this measuring device, a radio wave absorber is mounted on the whole inner surface thereof, an upper half portion thereof is formed in a pyramidal shape, and a circular polarized wave antenna is mounted on the top thereof, wherein the direction of the antenna is substantially aligned with a center line of the pyramidal shaped portion, and small-sized radio wave equipment to be measured is arranged at an a location to face the antenna, whereby the measuring device can be miniaturized.

[Patent Document 1]

Japanese Unexamined Patent Publication No. Hei 10 (1998)-13296

[Patent Document 2]

Japanese Unexamined Patent Publication No. 2001-116784

### SUMMARY OF THE INVENTION

A non-contact type RFID (Radio Frequency Identification) tag is a device which stores predetermined data in a memory circuit inside of a semiconductor chip and enables reading of the data using microwaves.

An IC inlet for the non-contact type tag is constituted of, for example, an antenna for receiving microwaves, which antenna is made of a Cu foil that is adhered to one surface of a rectangular insulating film, and a semiconductor chip, which is connected to the antenna and then sealed by a potting resin. Accordingly, the IC inlet of the non-contact type tag has the characteristics that the tag is thin and has extremely small profile dimensions.

To fabricate such an IC inlet, an elongated insulating film is prepared, on which a large number of antennas are formed at a predetermined interval, and semiconductor chips are connected to a large number of antennas that are formed on the insulating film. Thereafter, the semiconductor chips are sealed by resin molding.

In an inspection step in which the IC inlets that have been fabricated in this manner are separated into non-defective inlets and defective inlets, microwaves having the same frequency as the frequency employed in actual use are irradiated to the IC inlets that have been formed on the insulating film through reader antennas so as to read data written in the semiconductor chip.

At the time of reading the data of the IC inlet during actual use, to surely read the data even when the relative position between the antenna for reading and the IC inlet is slightly displaced, an antenna which transmits microwaves having wide range azimuth characteristics, such as circular polarized waves, is used. However, when the circular polarized waves are irradiated to the IC inlets that have been formed on the insulating film, the microwaves are irradiated to other IC inlets than the IC inlets to be inspected, and, hence, the microwaves reflected by the antennas of the IC inlets interfere with each other, whereby a highly accurate inspection cannot be performed.

On the other hand, a method in which the irradiation of microwaves is effected after cutting the insulating film so as to separate the IC inlets into individual pieces makes the handling of the IC inlets cumbersome, and, hence, such a method is not favorable from a realistic point of view.

It is an object of the present invention to provide a technique which can be used to inspect IC inlets with high accuracy to determine whether the IC inlets to be inspected are non-defective or defective in a state in which a large number of the IC inlets are formed on an insulating film.

It is another object of the present invention to provide a technique which can reduce the fabrication cost of small-sized IC inlets.

The above-mentioned, other objects and novel features of the present invention will become apparent from the description provided in this specification and from the attached drawings.

A summary of representative aspects of the invention disclosed in this specification will be presented as follows.

A method of fabrication of IC inlets according the present invention includes the steps of:

(a) separating a plurality of semiconductor chips having memory circuits in which predetermined data are written into individual pieces from a semiconductor wafer;

(b) preparing an insulating film in a state in which a plurality of antennas which receive radio waves of a predetermined frequency are separated from each other;

(c) connecting the semiconductor chips to the plurality of respective antennas formed on the insulating film;

(d) forming a plurality of IC inlets on the insulating film by sealing the respective semiconductor chips after performing the step (c); and

(e) inspecting whether the plurality of IC inlets are non-defective or defective by selectively irradiating radio waves of the predetermined frequency to the plurality of respective IC inlets formed on the insulating film.

### BRIEF DESCRIPTION OF THE DRAWINGS

FIG. 1 is a plan view (front surface side) showing an IC inlet according to one embodiment of the present invention;

FIG. 2 is a plan view showing a portion in FIG. 1 in an enlarged manner;

FIG. 3 is a side view showing the IC inlet according to the present invention;

FIG. 4 is a plan view (back surface side) showing the IC inlet according to the present invention;

FIG. 5 is a plan view showing a portion in FIG. 4 in an enlarged manner;

FIG. 6 is an enlarged plan view (front surface side) of part of the IC inlet according to the present invention;

FIG. 7 is an enlarged plan view (back surface side) of part of the IC inlet according to the present invention;

FIG. 8 is a circuit block diagram of the semiconductor chip which is mounted on the IC inlet according to the present invention;

FIG. 9 is a flow chart showing the method of fabrication of the IC inlet of the one embodiment of the present invention;

FIG. 10 is a plan view of a semiconductor wafer showing a method of fabrication of IC inlets according to the present invention;

FIG. 11 is a plan view of an insulating film showing a method of fabrication of IC inlets according to the present invention;

FIG. 12 is a plan view showing a portion in FIG. 11 in an enlarged manner;

FIG. 13 is a diagram of an inner lead bonder showing a portion of the step used in fabrication of the IC inlets (step of connecting semiconductor chips and antennas) according to the present invention;

FIG. 14 is a diagram showing part of the inner lead bonder shown in FIG. 13 in an enlarged manner;

FIG. 15 is an enlarged plan view of part of an insulating film showing a portion of the steps used in the fabrication of the IC inlets (step of connecting semiconductor chips and antennas) according to the present invention;

FIG. 16 is a diagrammatic cross-sectional view showing a portion of the steps used in the fabrication of the IC inlets (step of sealing semiconductor chips by resin molding) according to the present invention;

FIG. 17 is an enlarged plan view of part of an insulating film showing a portion of the steps used in the fabrication of the IC inlets (step of sealing semiconductor chips by resin molding) according to the present invention;

FIG. 18 is a diagram showing the whole constitution of an IC inlet inspection apparatus which constitutes one embodiment of the present invention;

FIG. 19 is a diagram showing a portion (black box) of the inspection apparatus shown in FIG. 18;

FIG. 20 is a diagrammatic perspective view showing a method of inspection of IC inlets according to the present invention;

FIG. 21 is a diagrammatic perspective view showing a method of inspection of IC inlets according to the present invention;

FIG. 22 is a diagrammatic perspective view showing a method of inspection of IC inlets according to the present invention;

FIG. 23 is a diagram showing a portion (black box) of an inspection apparatus for inspection of IC inlets according to the present invention;

FIG. 24 is an enlarged plan view of part of an insulating film showing the method of inspection of IC inlets according to the present invention;

FIG. 25 is a diagram illustrating the shipping of the IC inlets that have been fabricated according to the present invention;

FIG. 26 is a diagram showing the manner of using the IC inlets that have been fabricated according to the present invention;

FIG. 27 is an enlarged plan view of part of an insulating film showing a method of inspection of IC inlets according to the present invention;

FIG. 28 is a diagram showing a portion (black box) of an inspection apparatus for inspection of IC inlets according to the present invention;

FIG. 29 is an enlarged plan view of part of an insulating film showing the method of inspection of IC inlets according to the present invention;

FIG. 30 is an enlarged plan view of part of an insulating film showing the method of inspection of IC inlets according to the present invention;

FIG. 31 is an enlarged plan view of part of an insulating film showing the method of inspection of IC inlets according to the present invention;

FIG. 32 is an enlarged plan view of part of an insulating film showing the method of inspection of IC inlets according to the present invention;

FIG. 33 is a perspective view showing part of an inspection apparatus used in accordance with the present invention;

FIG. 34 is a perspective view showing a portion of a guide rail of the inspection apparatus shown in FIG. 33;

FIG. 35 is a plan view of the guide rail of the inspection apparatus shown in FIG. 33 as viewed from above;

FIG. 36 is a cross-sectional view of the guide rail taken along a line A-A in FIG. 35;

FIG. 37 is a cross-sectional view of the guide rail taken along a line B-B in FIG. 35;

FIG. 38 is a perspective view showing a method of inspection of IC inlets according to the present invention;

FIG. 39 is a perspective view showing a method of inspection of IC inlets according to the present invention;

FIG. 40 is a perspective view showing another example of a wave director mounted on the inspection apparatus shown in FIG. 33;

FIG. 41 is a diagram of an ID tag leader which constitutes another embodiment of the present invention;

FIG. 42 is a diagram showing a method of reading data using the ID tag reader shown in FIG. 41;

FIG. 43 is a diagram showing another example of a method of reading data using the ID tag reader;

FIG. 44 is a diagram showing a method of reading data of goods according to the present invention;

FIG. 45 is a perspective view showing another example of a wave director used for reading data of IC inlets;

FIG. 46 is a perspective view showing another example of a wave director used for reading data of IC inlets;

FIG. 47 is a cross-sectional view showing a method of fabrication of IC inlets according to the present invention; and

FIG. 48 is a cross-sectional view showing a method of fabrication of IC inlets according to the present invention.

### DESCRIPTION OF THE PREFERRED EMBODIMENTS

Embodiments of the present invention will be explained hereinafter in conjunction with the drawings. In all of the drawings, the same symbols are applied to identical parts, in principle, and a repeated explanation thereof will be omitted.

The details of the structure, the manner of operation, the design, the fabrication, the application and the like of the IC inlet, which constitutes a main object of the present invention, is described in the following patent applications that have been filed by the inventors of the present invention, et al., and, hence, a description thereof is not repeated, in principle. That is, the details of the IC inlet are described in Japanese Patent Application 2001-300841 (filed on Sep. 28, 2001) and corresponding U.S. application Ser. No. 10/256,026 (filed on Sep. 27, 2002), Japanese Patent Application 2002-209601 (filed on Jul. 18, 2002), and Japanese Patent Application 2002-247990 (filed on Aug. 28 2002).

In conjunction with the present invention, the IC inlet is a memory-antenna assembled body which includes an information storage integrated circuit element, such as a mask ROM (Read Only Memory) in a broad definition and an EEPROM (Electrically Rewritable Read Only Memory), and an antenna which is connected to the information storage integrated circuit element. In principle, all individual IC inlets store information different from each other. In operation, radio waves, such as microwaves (although radio waves having other wavelength may be used, the microwaves are advantageous in view of handling, range, directivity and the like), are irradiated to the IC inlet, or to an IC tag which includes the IC inlet, so as to make the IC tag or the IC inlet output radio waves. Then, by receiving such radio waves, information inside the radio waves are read and an origin, a producer, quality and other properties of a product can be identified based on the received information.

In accordance with the present invention, respective individual IC inlets hold different information by writing the ROM information individually by directly drawing electron lines as the mask ROM in a broad definition. This is so that a remarkably high degree of freedom is ensured compared to the rewriting of a ROM using a mask, and, at the same time, the turn-around time can be largely reduced.

It is also possible to use an EEPROM. In this case, there is an advantage in that rewriting can be performed later if necessary or the like is obtained. Still further, since the preparation of masks is unnecessary and a wafer step, such as the direct drawing of electron lines or the like, is unnecessary, it is also possible to obtain an advantage in that information can be electrically written directly from the beginning. On the other hand, with respect to the mask ROM in a broad definition, since rewriting from the outside is impossible, this brings about a large advantage in that the reliability of the information is ensured. However, even when a flash memory or other EEPROM is used, by making the rewriting impossible using a method which makes a rewriting circuit inoperable (or making a memory cell per se incapable of rewriting) after the writing of information, or simultaneously with the writing of information, it is also possible to ensure a similar reliability.

In accordance with the present invention, a radio-wave power-supply type IC inlet or a battery free type IC inlet (an intrinsic information holding memory and an antenna assembled body) receives radio waves from the outside, rectifies the radio waves and, thereafter, supplies radio waves. However, it is needless to say that the respective features of the invention as described in this specification are applicable to a battery power supply-type IC inlet or a self power-supply type IC inlet as well. The radio-wave power-supply type IC inlet is characterized in that it is small-sized and is free from drawbacks caused by the leaking of battery liquid, such as chemical corrosion and chemical burns, since the IC inlet has no battery. Accordingly, the radio-wave power-supply type IC inlet can be attached to an article in a state where the IC inlet is accommodated in an IC tag, or the radio-wave power-supply type IC inlet can be directly accommodated in any article that user wears. Here, the IC tag is a thin piece, such as a tag, and is formed of an IC inlet holding plate-like body, which accommodates the IC inlet therein. A major portion of the IC tag is mainly formed of paper, a plastic sheet, an elastomer sheet, a conductive material sheet, a laminated sheet made of these sheets, or a plate-like material which constitutes a major constitutional element.

Main usages or applications of the IC tag (IC tag having an auxiliary wave director to be described hereinafter) and the IC inlet of the present invention are as follows.

(1) The IC tag or the IC inlet is incorporated into the inside of an IC card so as to authenticate that the card is genuine.

(2) The IC inlet (TCP type being suitable, and also applicable to the explanation to be given hereinafter) is directly incorporated into an admission ticket, a gift certificate or bill, or the admission ticket or the like per se is formed into the IC tag, so that it is possible to authenticate whether the admission ticket or the like is genuine. Here, by providing an IC tag having an auxiliary wave director, the following advantages can be obtained. The same applies to the explanation made hereinafter. Further, it is possible to perform the management, such as the specifying of individual admission tickets and users.

(3) It is possible to authenticate whether stock certificates or securities are genuine or not. Further, it is possible to perform the management of the individual certificates and holders.

(4) By mounting or incorporating the IC tag or IC inlet into the lid of a bottle, it is possible to prevent the erroneous handling of medicines. Further, it is possible to utilize the IC tag or the IC inlet in the management of dangerous medicines or the like.

(5) By directly incorporating the IC inlet into a label which is adhered to a food or the like, or by forming the label per se into an IC tag, it is possible to authenticate whether information on the origin, brand, producer, raw material or the like of the food is genuine or not.

(6) By embedding an IC inlet or an IC tag into a material of a brand product or by mounting the IC inlet or the IC tag on the material, it is possible to authenticate whether the brand product is a genuine good or not.

(7) By mounting an IC inlet or an IC tag to a metal product by way of an insulation sheet (the sheet per se may be formed as a measure portion of the tag) having a thickness of approximately several mm, it is possible to authenticate the attribution, a producer and genuineness of the metal product. Further, it is also possible to utilize the IC inlet or the IC tag for the management such information. Particularly, when the metal product is huge (heavy and hence able to be easily moved), the use of the IC inlet or the IC tag is particularly advantageous.

(8) By attaching the IC inlet or the IC tag to a book in the library, the IC inlet or the IC tag can be utilized for the management of lent books.

Besides, the above-mentioned applications, in a retail trade involving the sale of goods, it is possible to use the IC inlet or the IC tag for authenticating the origin or the like of goods.

(9) The IC tag provided with an auxiliary wave director is effective when reading is particularly difficult. That is, when it is necessary to ensure a given distance between the IC tag and a reader, or when the IC tag is used in a state in which the IC tag is attached to a huge object or in a stacked state or when it is necessary to change the direction of radio waves, the IC tag provided with the auxiliary wave director is effective.

### Embodiment 1

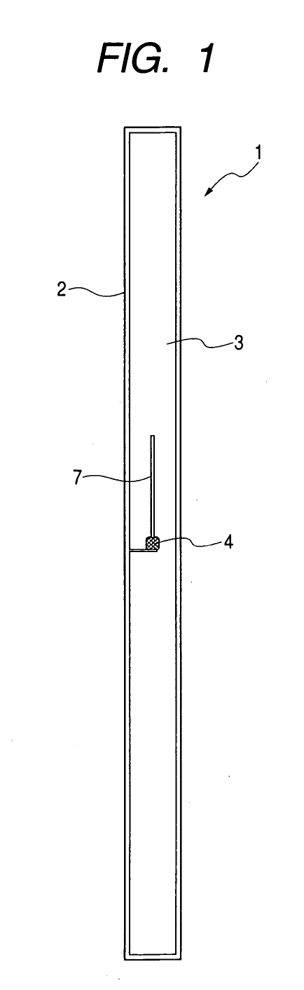

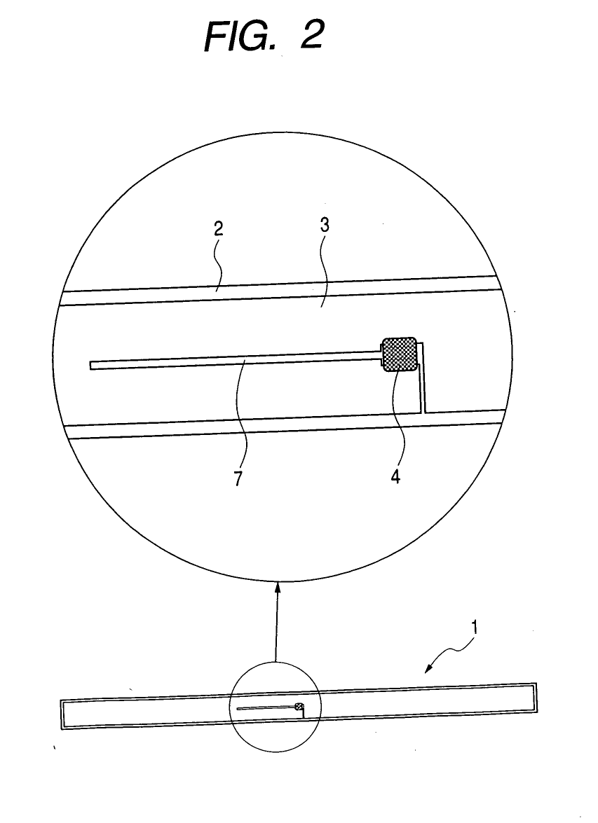

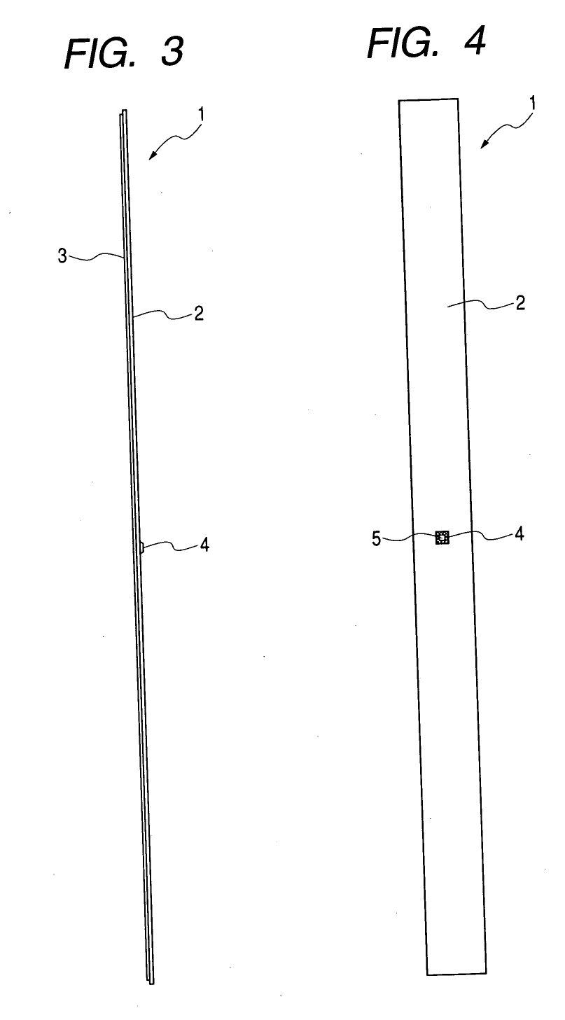

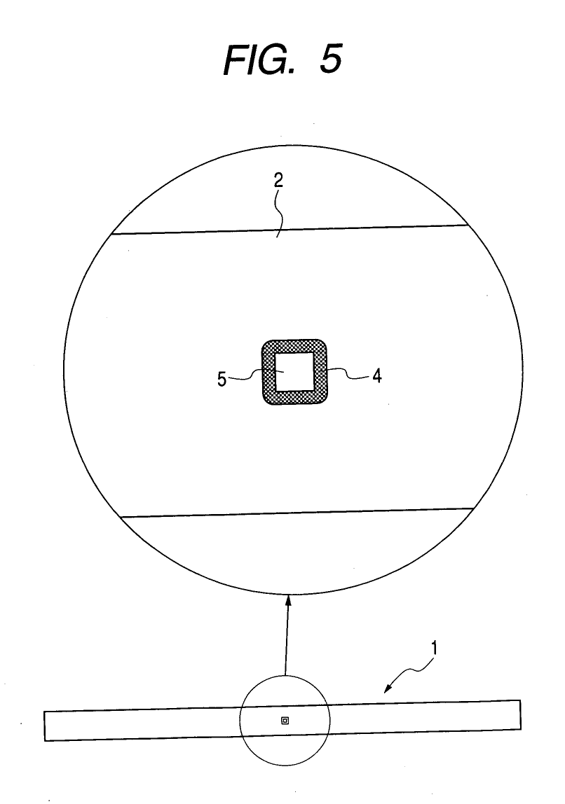

FIG. 1 is a plan view (front surface side) showing an IC inlet of this embodiment, FIG. 2 is a plan view showing a portion of FIG. 1 in an enlarged form, FIG. 3 is a side view showing the IC inlet of this embodiment, FIG. 4 is a plan view (back surface side) showing the IC inlet of this embodiment, and FIG. 5 is a plan view showing a portion of FIG. 4 in an enlarged form.

The IC inlet 1 of this embodiment is constituted of an antenna 3 for receiving microwaves, which antenna is formed of a Cu foil that is adhered to one surface of an elongated rectangular insulating film 2 and a semiconductor chip 5 which is connected to the antenna 3 in a state in which the semiconductor chip 5 is sealed by potting resin 4. Although the profile size of the IC inlet 1 is set such that, as an example, the length is 53 mm, the width is 2.4 mm and the thickness is 0.6 mm, so long as microwaves having a specific frequency (for example, 2.45 GHz; wavelength approximately 122 mm), which are transmitted from a reader apparatus to be described later, can be efficiently received, the profile size of the IC inlet 1 is not is limited to the above-mentioned size.

In a substantially center portion of the antenna 3, an L-shaped slit 7 is formed so that one end thereof is located at an outer periphery of the antenna 3, while the semiconductor chip 5, which is sealed by the potting resin 4, is mounted on an intermediate portion of the slit 7.

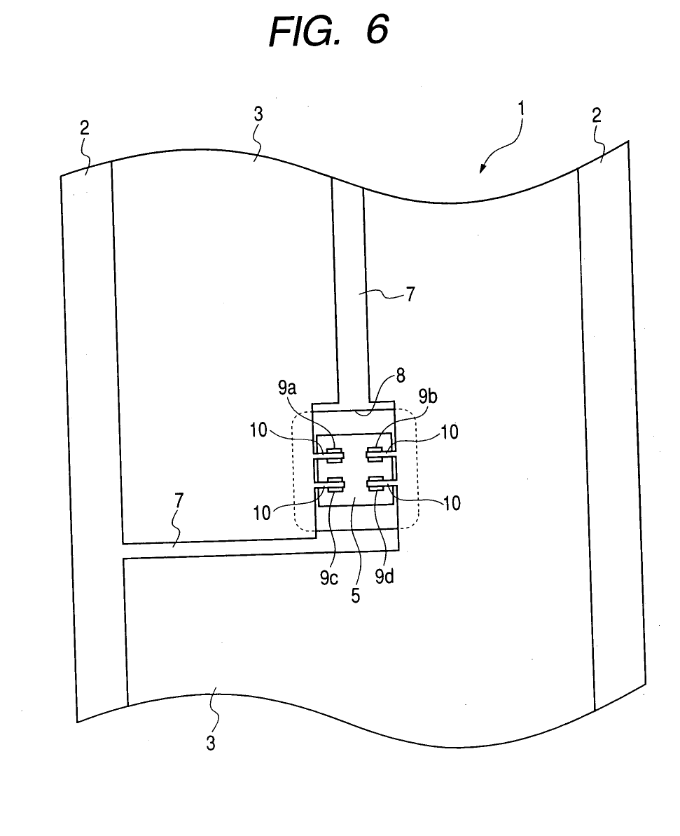

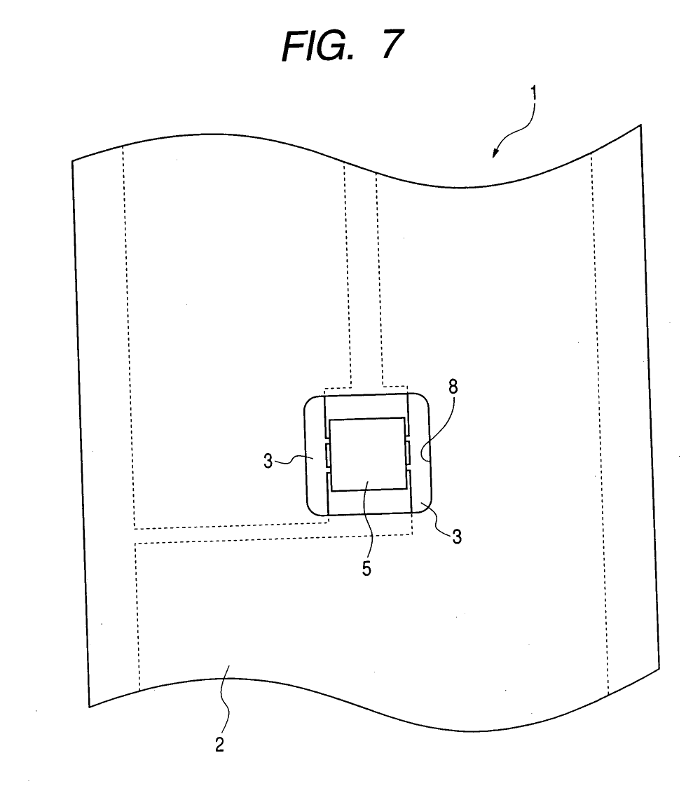

FIG. 6 and FIG. 7 are enlarged plan views showing the vicinity of the center portion of the antenna 3 where the above-mentioned slit 7 is formed, wherein FIG. 6 shows the front-surface-side of the IC inlet 1 and FIG. 7 shows the back surface side of the IC inlet 1. In these drawings, the potting resin 4 which seals the semiconductor chip 5 is omitted.

As shown in the drawing, in the intermediate portion of the slit 7, a device hole 8 is formed by punching out a portion of the insulating film 2, and the semiconductor chip 5 is arranged at the center portion of the device hole 8. That is, the IC inlet 1 of this embodiment is constituted to have a TCP (Tape Carrier Package) structure. The size of the device hole 8 is set such that, for example, the longitudinal size×lateral size=0.8 mm×0.8 mm, while the size of the semiconductor chip 5 is set such that longitudinal size×lateral size=0.4 mm×0.4 mm.

As shown in FIG. 6, on a main surface of the semiconductor chip 5, for example, four Au bumps 9 (9a, 9b, 9c, 9d) are formed. These Au bumps 9 are formed using a well-known electrolytic plating method, for example, wherein the height of the Au bumps 9 is approximately 15 μm, for example. Further, these respective Au bumps 9 are integrally formed with the antenna 3 and have one end thereof connected to leads 10 which extend inside the device hole 8.

Among the above-mentioned four leads 10, two leads 10 extend from one of the regions which are separated from each other with the slit 7 therebetween to the inside of the device hole 8 and are electrically connected with the Au bumps 9a, 9c of the semiconductor chip 5. Further, the remaining two leads 10 extend from another one of the above-mentioned regions to the inside of the device hole 8 and are electrically connected with the Au bumps 9b, 9d of the semiconductor chip 5.

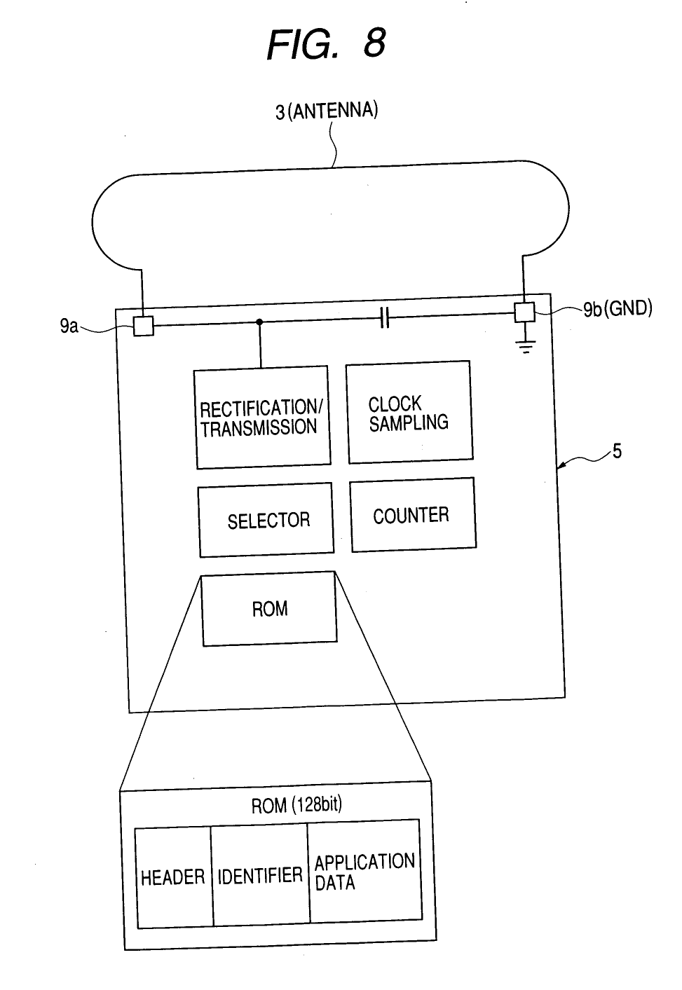

The semiconductor chip 5 is formed of a single crystal silicon substrate having a thickness of approximately 0.15 mm and, on a main surface thereof, various circuits, including a rectification/transmission circuit, a clock sampling circuit, a selector circuit, a counter circuit and a ROM are formed as shown in FIG. 8. Among the above-mentioned four Au bumps 9 (9a, 9b, 9c, 9d), for example, the Au bump 9a constitutes an input terminal of the circuits shown in FIG. 8 and the Au bump 9b constitutes a GND terminal. Further, the remaining two Au bumps 9c, 9d constitute dummy bumps which are not connected to the above-mentioned circuits, wherein the dummy bumps (Au bumps 9c, 9d) are provided for increasing the contact area between the Au bumps 9 and the leads 10, so as to ensure the connection reliability between them.

In the ROM formed on the semiconductor chip 5, data of 128 bits, including application data corresponding to the usage of the IC inlet 1, an identifier peculiar to every IC inlet and a header, are written. The ROM which is a type of non-volatile semiconductor memory has an advantage in that the storage capacity is large compared to other types of storage medium, such as bar codes. Further, the data stored in the ROM has an advantage in that an illegal falsification is difficult compared to a storage medium, such as bar codes, and, hence, the reliability is enhanced also with respect to security.

The structure of the above-mentioned IC inlet 1 is described in further detail in Japanese patent application 2002/247990, filed by the inventors of the present invention.

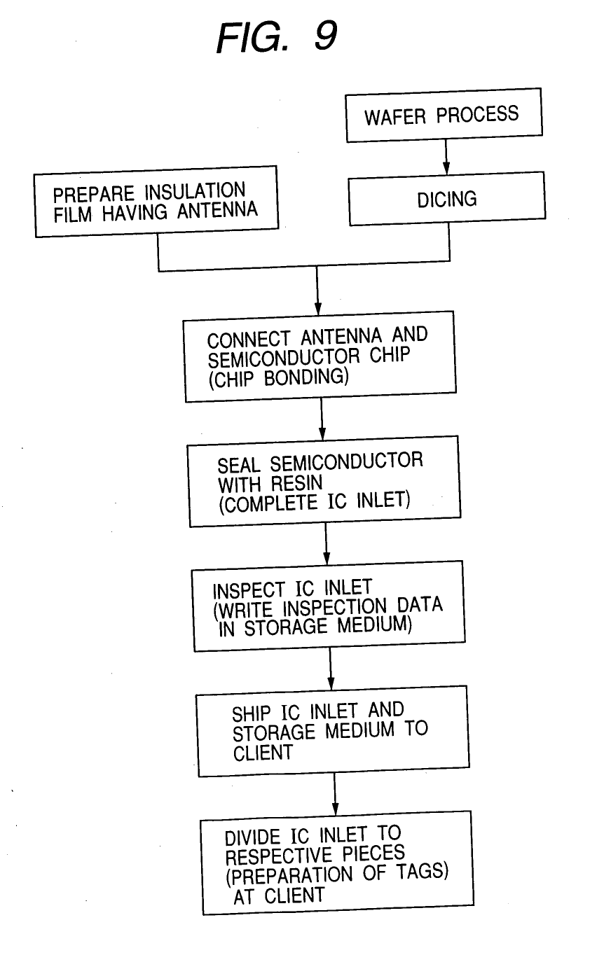

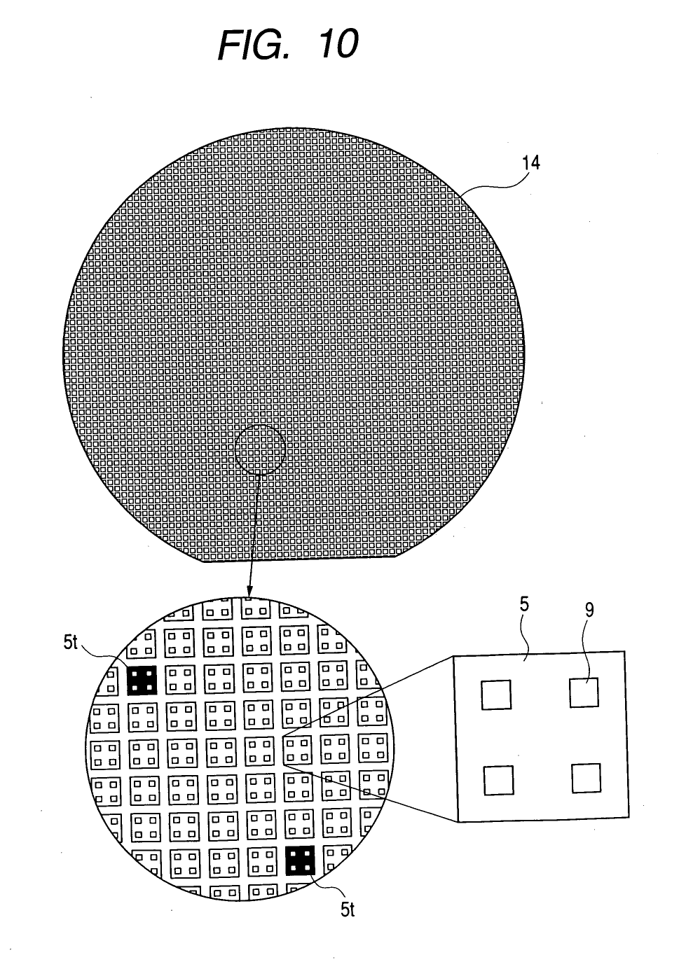

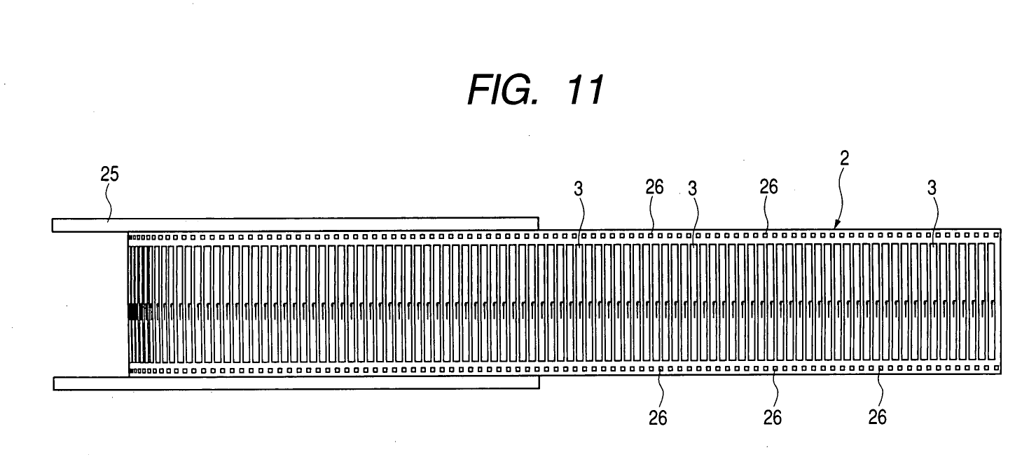

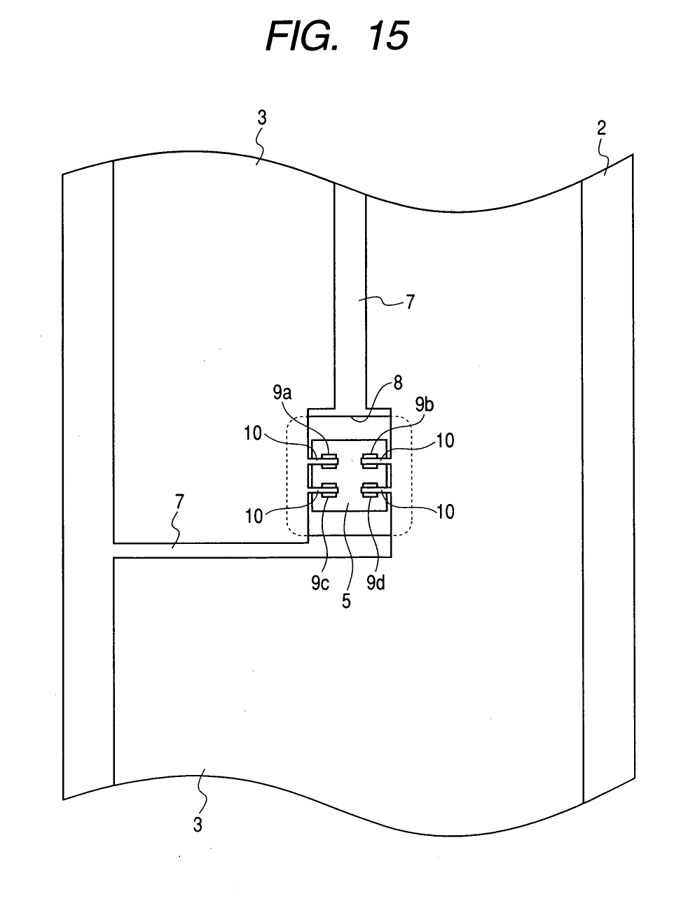

Next, a method of manufacturing an IC inlet 1, which has the above-mentioned constitution, will be explained in the order of the steps thereof in conjunction with FIG. 9 (overall flow chart) and FIG. 10 to FIG. 26.

First, as shown in FIG. 10, the above-mentioned circuits and the Au bumps 9, which are shown in FIG. 8, are formed on each of a large number of semiconductor chips (chip regions) 5 which are defined on the main surface of a silicon wafer 14 by employing a well-known semiconductor manufacturing process. Thereafter, the silicon wafer 14 is diced so as to separate the semiconductor chips 5 into individual pieces. At this time, in this embodiment, for simplifying the manufacturing steps, the electric characteristics test (probe inspection) of the individual semiconductor chips (chip regions) 5, which is usually performed before dicing, is omitted. Alternatively, as shown in the drawing, only a simple inspection which checks for the presence or the non-presence of an open/short-circuit, the function of the ROM, the margin of fluctuation of the power-source voltage (Vdd) or the like may be performed by forming test chips 5t at a plurality of spots on the silicon wafer 14 and by bringing the probe into contact with terminals (Au bump 9) of the test chips 5t.

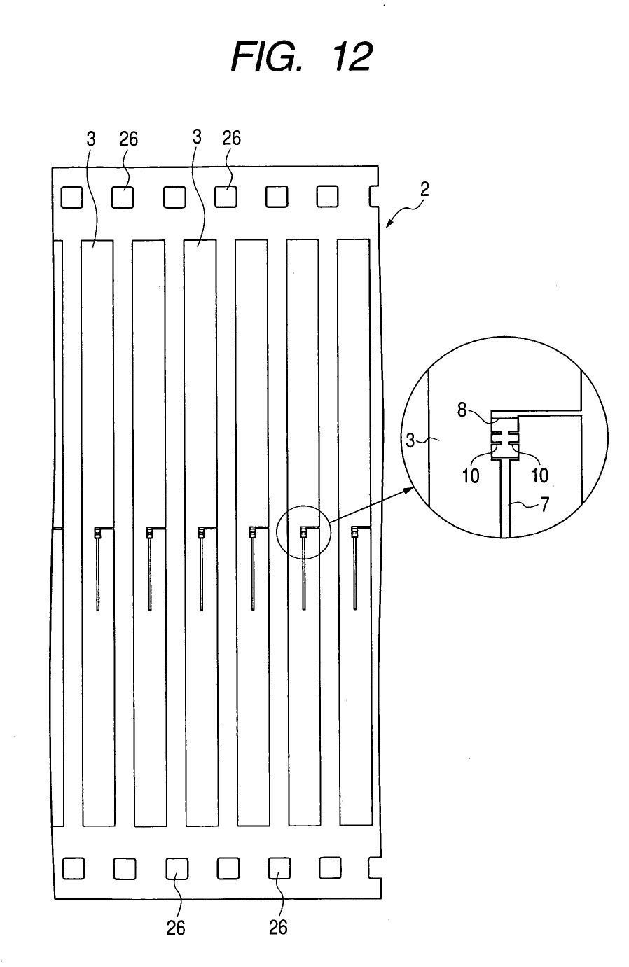

On the other hand, along with the fabrication of the semiconductor chips 5, an elongated insulating film 2 is prepared, on which a large number of antennas 3 are formed. FIG. 11 is a plan view of the insulating film 2 and FIG. 12 is a plan view showing a part of FIG. 11 in an enlarged form.

On one surface of the insulating film 2 that is made of a polyimide resin having a thickness of approximately 75 μm, for example, a large number of antennas 3 are formed at a predetermined interval. These antennas 3 are formed, for example, by bonding a Cu foil having a thickness of approximately 18 μm to one surface of the insulating film 2 and patterning the Cu foil into the shape of antenna 3 using a photolithography technique. At this time, the above-mentioned slits 7 and leads 10 are formed on the respective antennas 3 and, thereafter, Su (tin) plating is applied to the surfaces of the leads 10.

Further, for example, the antennas 3, having the slits 7 and the leads 10, may be formed such that a first Cu film is formed on the insulating film 2 using a sputtering method, then, a second Cu film is formed on the front surface of the first Cu film using an electrolytic plating method, and, thereafter, these first and second Cu films are patterned. According to this method, IC inlets 1 having an extremely small thickness can be fabricated.

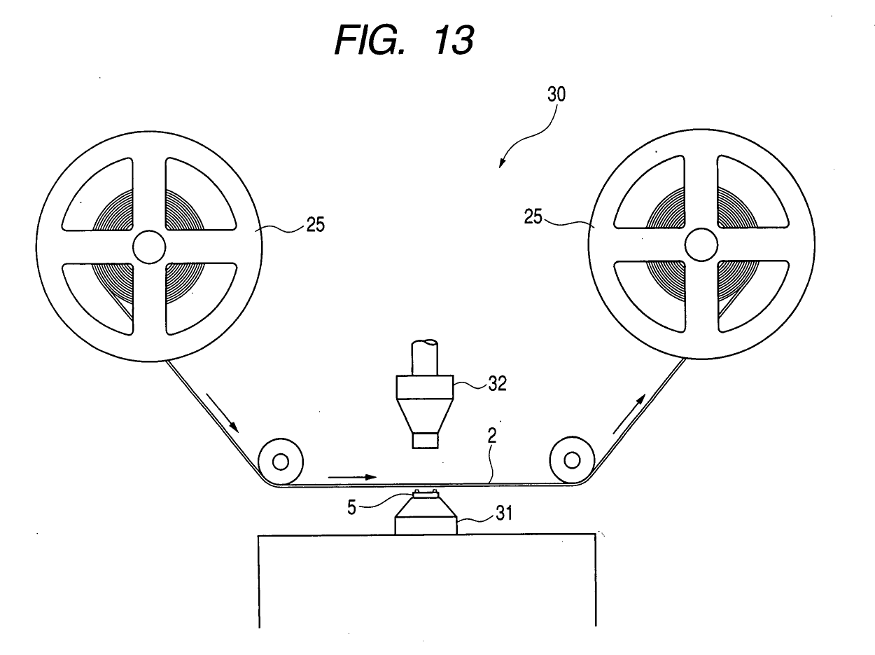

The above-mentioned insulating film 2 conforms to the TCP (Tape Carrier Package) Standard and is made of, for example, a polyimide resin film having a width of 50 μm or 70 μm and a thickness of 75 μm. The above-mentioned device hole 8 is formed in portions of the insulating film 2. Further, at both sides of the insulating film 2, sprocket holes 26 for transporting the insulating film 2 on a manufacturing line of IC inlets 1 are formed at predetermined intervals. The device holes 8 and the sprocket holes 26 are formed by punching out portions of the insulating film 2. The elongated insulating film 2, which is fabricated as shown in FIG. 13, is wound around a reel 25 and transported to a fabricating line of IC inlets 1.

Next, as shown in FIG. 13 to FIG. 15, the reel 25 is mounted on an inner lead bonder 30 which is provided with a bonding stage 31 and a bonding tool 32. Here, by moving the insulating film 2 along an upper surface of the bonding stage 31, the semiconductor chip 5 is connected to the antenna 3.

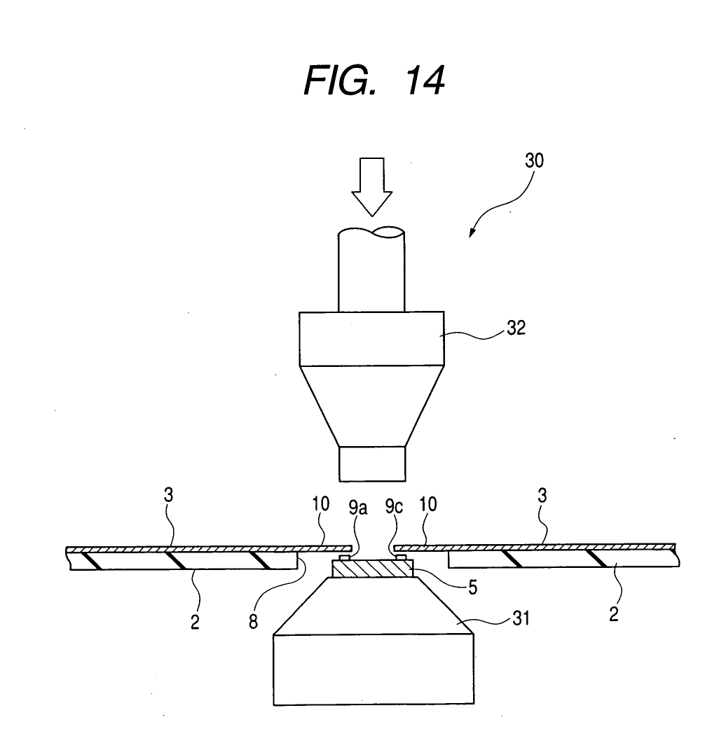

For connecting the semiconductor chip 5 to the antenna 3, as shown in FIG. 14 (enlarged view of part of FIG. 13), the semiconductor chip 5 is mounted on the bonding stage 31, which is heated to approximately 100° C. Right above this semiconductor chip 5, the device hole 8 of the insulating film 2 is positioned. Thereafter, the bonding tool 32, which is heated to approximately 400° C., is pressed to the upper surface of the leads 10 which are projected to the inside of the device hole 8 so as to bring the Au bump 9 (9a to 9d) and the lead 10 into contact with each other. Here, by applying a predetermined load to the bonding tool 32 for approximately 2 seconds, an Au—Sn eutectic alloy is formed at an interface between the Sn plating and the Au bumps 9 which are formed on the front surfaces of the leads 10, and the Au bump 9 and the lead 10 are adhered to each other.

Next, another semiconductor chip 5 is mounted on the bonding stage 31. Then, the insulating film 2 is moved by only one pitch of the antennas 3. Thereafter, by performing a similar operation as described above, a semiconductor chip 5 is connected to another antenna 3. Thereafter, by repeating similar operations as described above, the semiconductor chips 5 are mounted one by one on all of the antennas 3 which are formed on the insulating film 2. The insulating film 2, on which the connection between the semiconductor chips 5 and the antennas 3 is finished, is wound around the reel 25 and is transported to a location where a subsequent resin sealing step is performed.

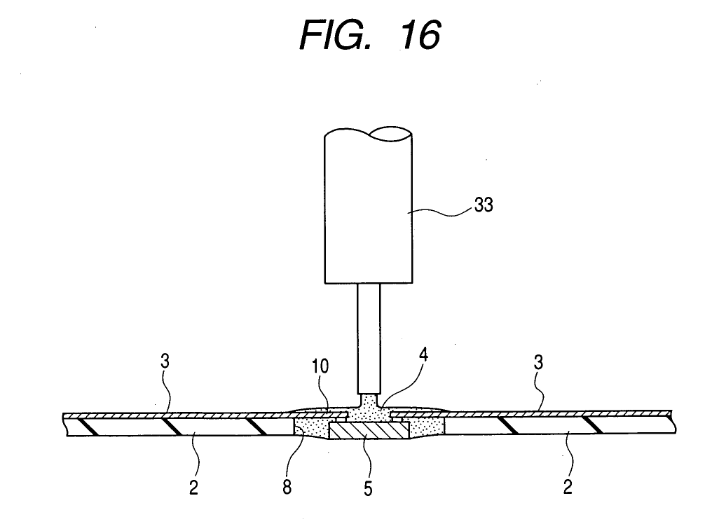

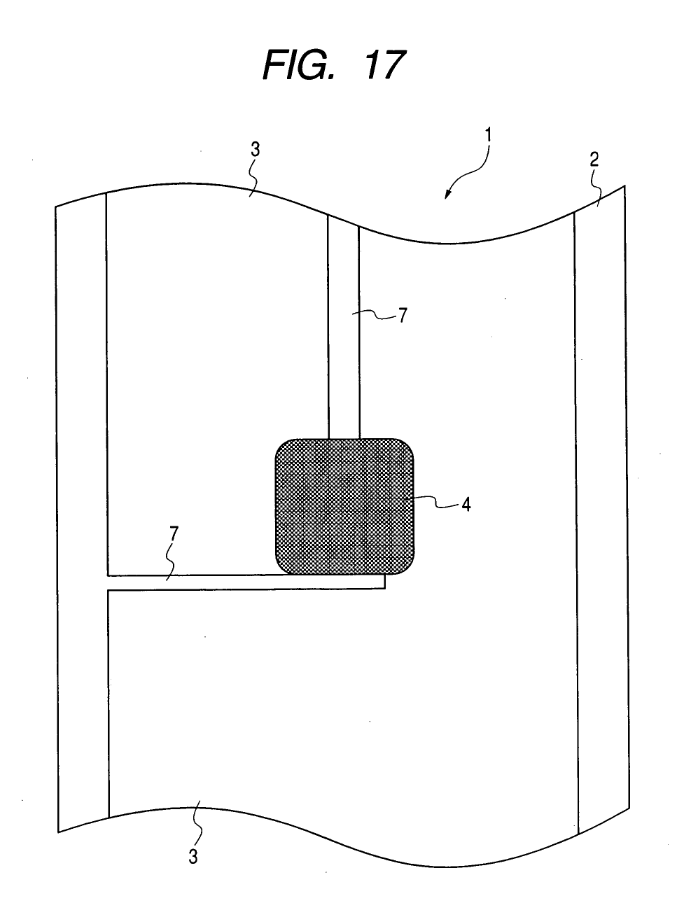

As shown in FIG. 16 and FIG. 17, in the resin sealing step, the potting resin 4 is supplied to the upper surface and the side surfaces of the semiconductor chip 5, which is mounted on the inner side of the device hole 8 using a dispenser 33 or the like. Thereafter, by baking the potting resin 4 in a heating furnace, the semiconductor chip 5 is sealed by resin. Due to the steps performed heretofore, the IC inlet 1 is almost completed. The insulating film 2 on which the IC inlets 1 are formed is wound around a reel 25 and is transported to the next inspection step.

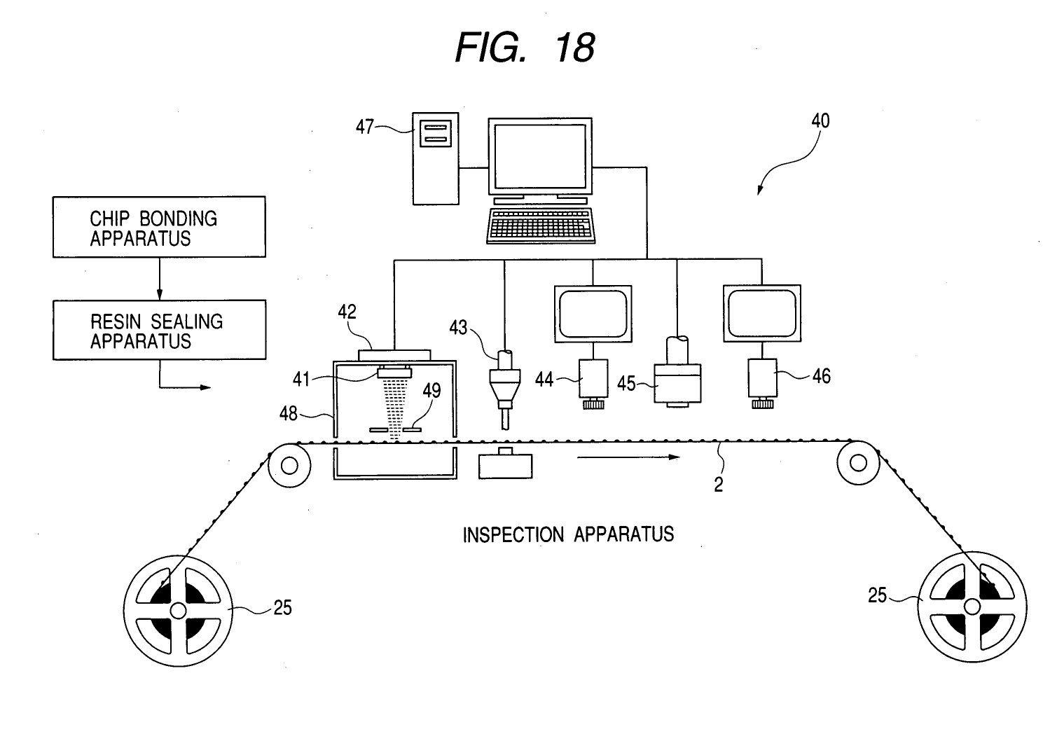

FIG. 18 is a diagram showing the overall constitution of an inspection apparatus 40 for performing the selection of the IC inlets 1. By providing this inspection apparatus 40 at a rear stage of the above-mentioned resin sealing step, the connection between the semiconductor chip 5 and the antenna 3 (chip bonding), the resin sealing and the inspection can be performed consistently on the same manufacturing line. Further, the inspection apparatus 40 may be mounted on another independent line, so that the inspecting operation can be performed separately from the operation for connecting the semiconductor chip 5 and the antenna 3, or the resin sealing operation.

The above-mentioned inspection apparatus 40 is constituted of a reader apparatus 42 which is provided with a reader antenna 41 for transmitting microwaves of 2.45 GHz, a punch 43 for forming holes, a first camera 44 for confirming the formation of the holes, a laser marker 45 for printing marks, a second camera 46 for appearance inspection, and a server 47 for collecting data which is connected to these apparatuses and components.

The reader apparatus 42 irradiates microwaves having the same frequency (2.45 GHz) as the frequency actually applied to the IC inlets 1 on the insulating film 2 through the reader antenna 41 in a non-contact state and inspects the operation of the circuits formed on the semiconductor 5 and the connection state between the semiconductor chip 5 and the antenna 3. Thereafter, the reader apparatus 42 transmits the inspection results to the server 47.

Here, in reading the data of the IC inlet 1 in actual use, to ensure reliable reading even when the relative position between the reader antenna and the IC inlet 1 is slightly displaced, the antenna which irradiates microwaves having wide-range azimuth characteristics, such as circular polarized waves, is used. On the other hand, in the above-mentioned inspection step, it is necessary that microwaves are irradiated to only one IC inlet 1 to be inspected among a large number of IC inlets 1 formed on the front surface of the insulating film 2 at a narrow interval, while the microwaves are not irradiated to other neighboring IC inlets 1. Accordingly, as the antenna 41 of the reader apparatus 42 which is used in the inspection step, an antenna which transmits microwaves having high directional characteristics, such as linearly polarized waves, or more favorably, a dipole, is used.

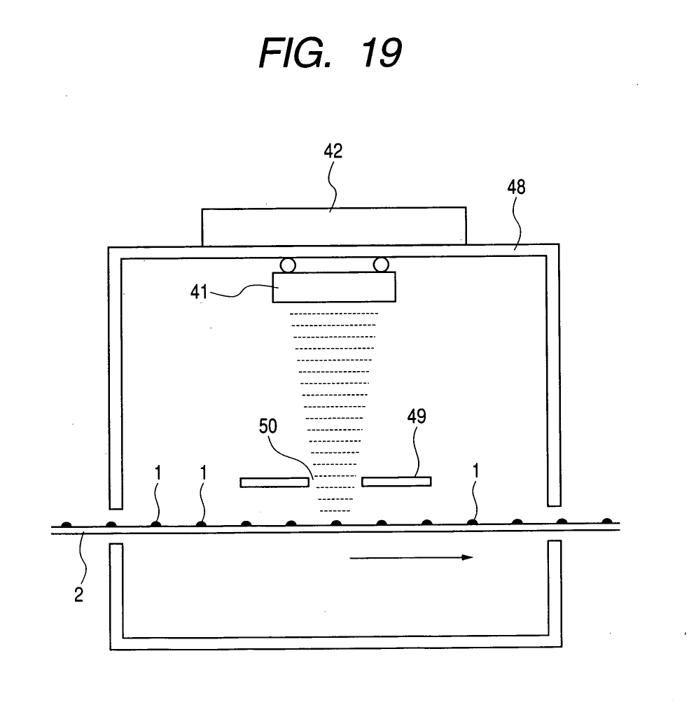

It is favorable that, as shown in FIG. 19, for example, the inspection of the IC inlet 1 using the above-mentioned reader apparatus 42 is performed in the inside of a black box 48 having a microwave absorption body (not shown in the drawing) on a whole inner surface thereof. By irradiating microwaves from the antenna 41 to the IC inlet 1 inside the black box 48, irregular reflection of the microwaves can be prevented, and disturbance radio waves from the outside can be also prevented, and, hence, the IC inlet 1 can be inspected with high accuracy.

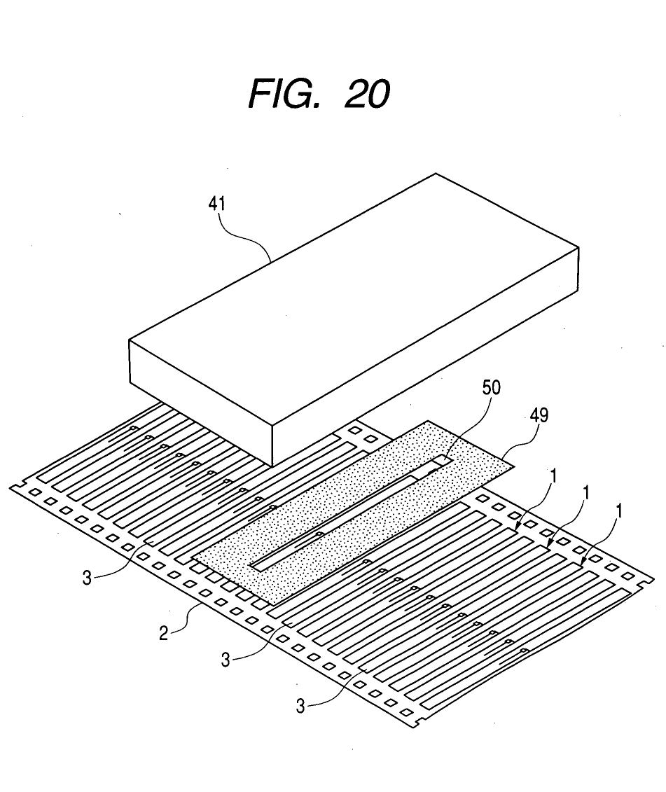

Further, as means which can selectively irradiate the microwaves to only one IC inlet 1 to be inspected, for example, as shown in FIG. 20, it is preferable to insert a radio-wave absorbing plate 49 between the insulating film 2 and the antenna 41 so that the microwaves can be irradiated to the IC inlet 1 through a slit 50 having the same opening size as the antenna 3, which slit is formed in this radio-wave absorbing plate 49.

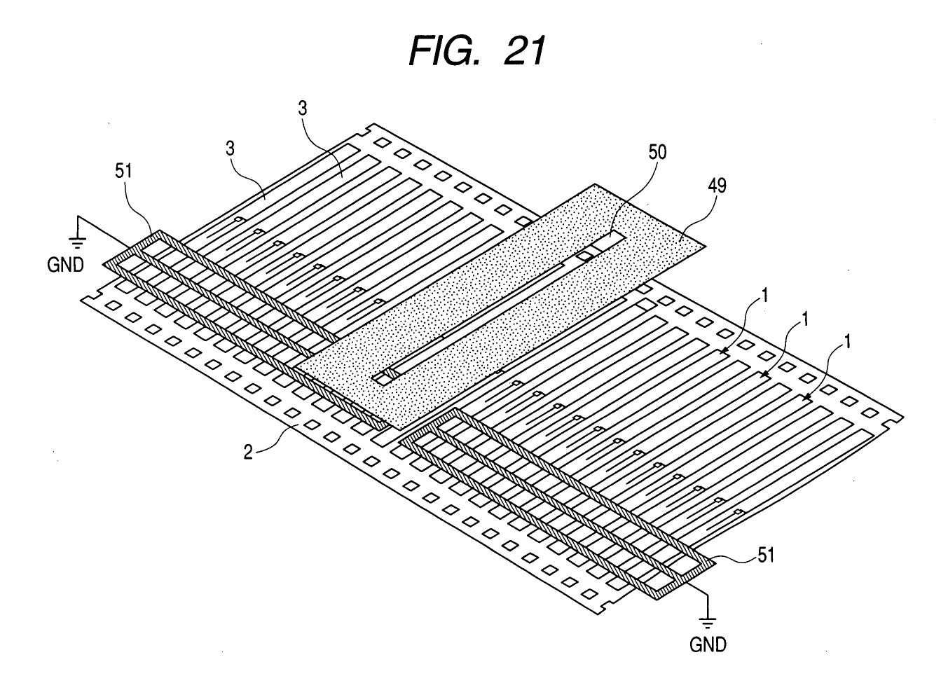

Further, it may be possible that, as shown in FIG. 21, by bringing a grounded conductive plate 51 made of metal into contact with the antennas 3 of the IC inlets 1, other than the IC inlet to be inspected, the radio-wave reflection performance of the grounded antennas 3 is lowered. Due to such a constitution, even when the microwaves are irradiated to the IC inlets 1 other than the IC inlet to be inspected, the interference between the microwaves which are reflected from the antenna 3 of the IC inlet 1 to be inspected and the microwaves which are reflected from the antennas 3 of the IC inlets 1, other than the IC inlet to be inspected, can be suppressed, and, hence, the inspection accuracy of the IC inlet 1 is further improved.

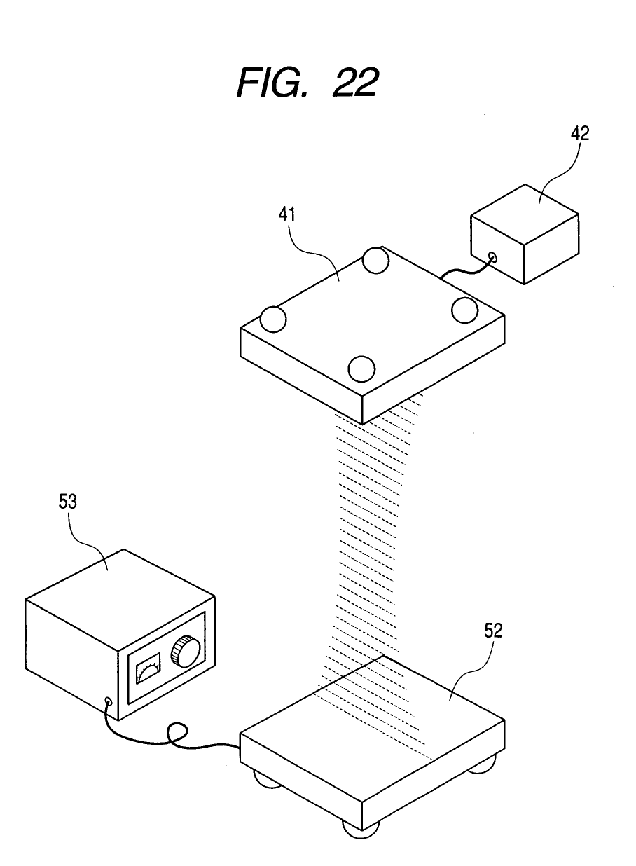

Further, when the inspection of the IC inlet 1 is performed using the above-mentioned reader apparatus 42, as shown in FIG. 22, it is preferable that the strength of the microwaves which are irradiated from the reader antenna 41 is preliminarily measured by a field strength meter 53 which is provided with a calibration antenna 52, and the distance between the IC inlet 1 and the antenna 41, or the strength of the microwaves which are outputted from the reader apparatus 42, are optimized. Further, by performing these operations periodically, a lowering of the inspection accuracy attributed to the time-sequential change of the strength of the microwave can be prevented.

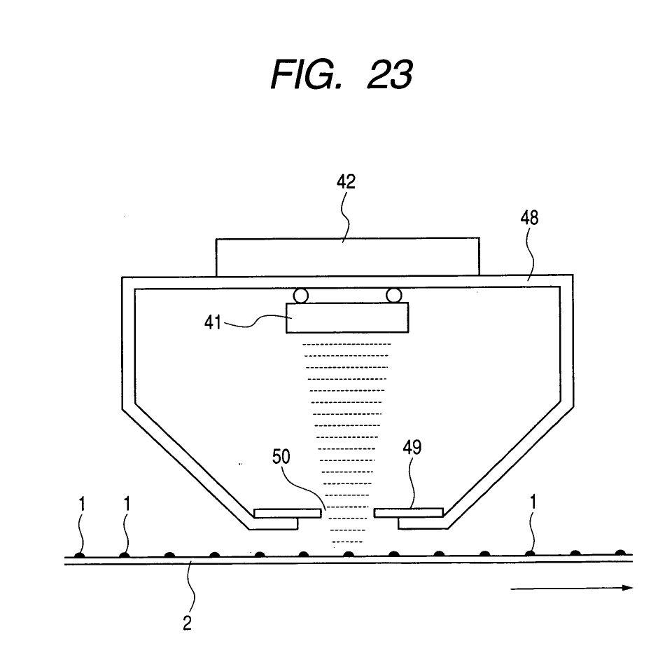

Further, the constitution of the above-mentioned black box 48 is not limited to the constitution shown in FIG. 19, and various design changes can be made. For example, as shown in FIG. 23, it is possible to perform the inspection by arranging the insulating film 2 outside the black box 48, which stores the reader antenna 41 and the radio-wave absorbing plate 49.

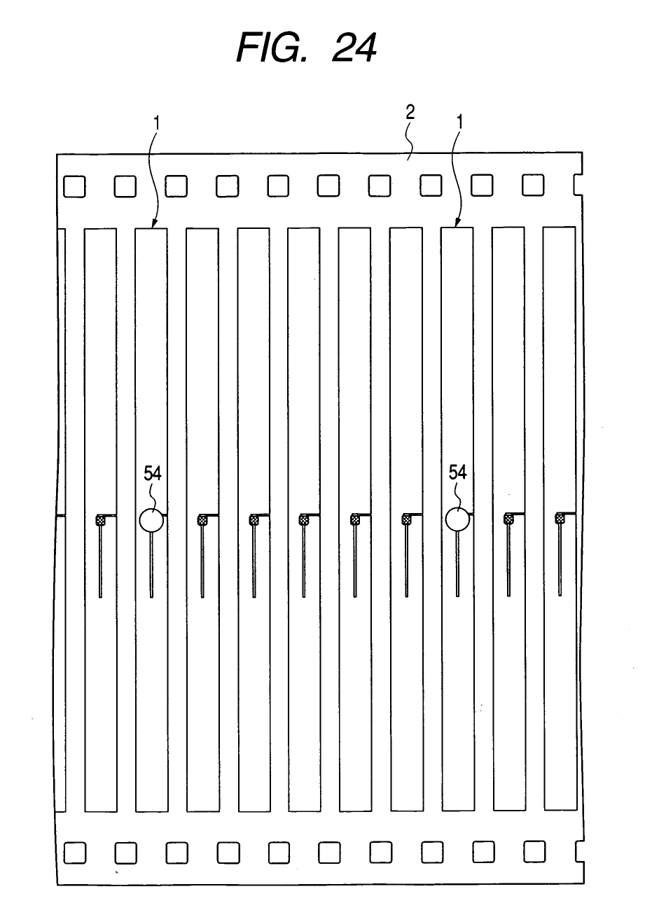

When the IC inlet 1 is determined to be defective as a result of inspecting the IC inlets 1 on the insulating film 2 one by one by using the above-mentioned inspection apparatus 40, as shown in FIG. 24, a hole 54 is punched out by a punch 43 for forming a hole, which is shown in the above-mentioned FIG. 18, and the semiconductor chip 5 is removed. The punch 43 is controlled such that the punch 43 punches out only the semiconductor chip 5 of the IC inlet 1, which is determined to be defective based on the inspection data which is transmitted from the reader apparatus 42 to the server 47. In this manner, by removing only the semiconductor chip 5 of the defective IC inlet 1 so as to prevent the semiconductor chip 5 from being transported to the outside, the security of the data which is written on the semiconductor chip 5 can be guaranteed.

The insulating film 2, which reaches the state where the above-mentioned inspection and the removal of the defective chip are completed, is transported to a position below a first camera 44, and it is confirmed by the first camera 44 whether the removal of the defective chip is surely performed or not (see FIG. 18). Then, based on data which is transmitted from the first camera 44 to the server 47, marks such as product types or the like are formed on the front surface of the non-defective IC inlet 1 using a laser marker 45.

When the insulating film 2 reaches the state where the marking is finished, the IC inlet 1 is subjected to an appearance inspection which is performed by a second camera 46 and, thereafter, is wound around the reel 25 (see FIG. 18). In this manner, the inspection of all of the IC inlets 1 which are formed on the insulating film 2 is continuously performed. On the other hand, the server 47 determines whether all of the IC inlets 1 on the insulating film 2 are non-defective or defective based on the data which has been collected so far and stores the data in the server 47.

The manufacturer of the IC inlet 1, based on the above-mentioned inspection data stored in the server 47, inspects the relationship between the address of the silicon wafer 14 shown in the above-mentioned FIG. 10 and the defective chips and performs an analysis of causes of the defects. Further, the inspection data stored in the server 47 is written in a storage media, such as a CD-ROM or the like, together with intrinsic data (identifier and header) for every IC inlet.

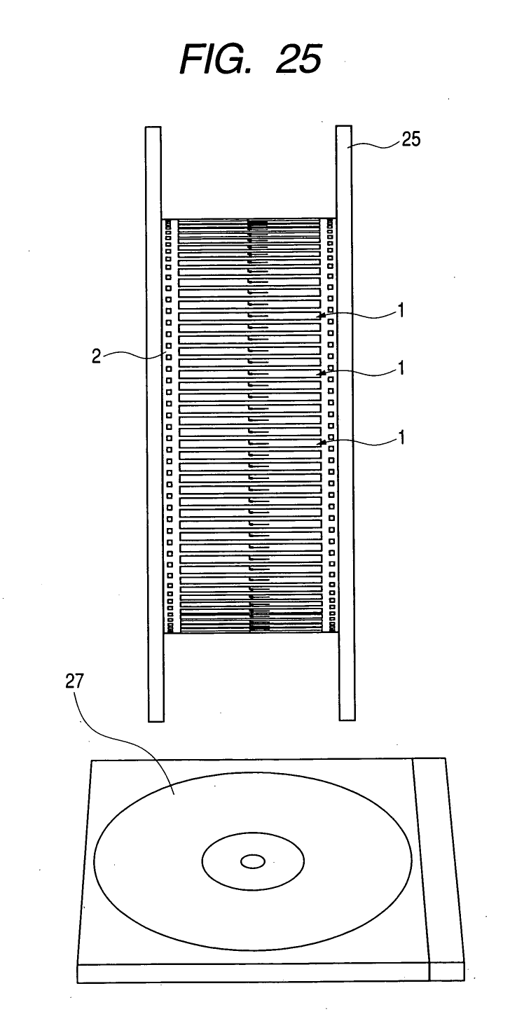

When the fabrication and the inspection of the IC inlets 1 are completed as mentioned above, as shown in FIG. 25, the insulating film 2 is packed in a state in which the insulating film 2 is wound around the reel 25 and is shipped to customers together with a CD-ROM 27, on which the inspection data is written.

The customers, such as tag makers or the like who purchase the above-mentioned IC inlets 1, can obtain the IC inlets 1 which are made into single pieces as shown in the above-mentioned FIG. 1 to FIG. 5 by cutting the insulating film 2 which is wound around the reel 25. Thereafter, the customer makes the tags by combining these IC inlets 1 and the other members. The tag maker can manage the tags based on the specific data for respective IC inlets, which are written on the above-mentioned CD-ROM 27.

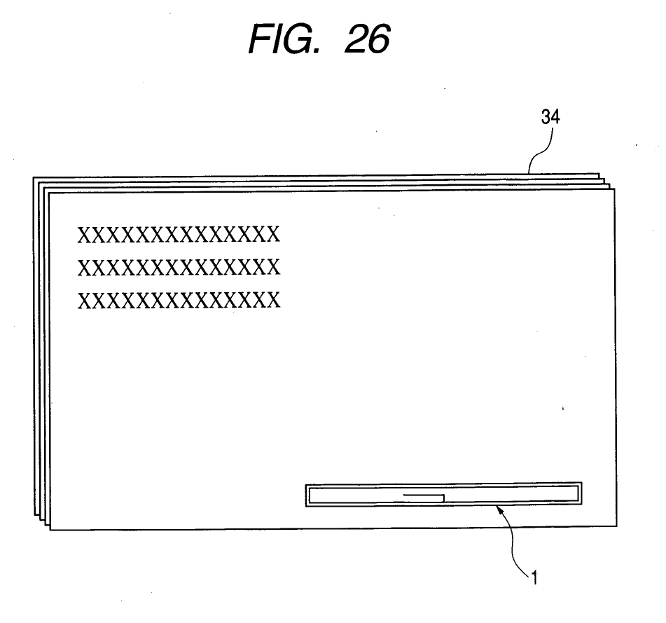

For example, FIG. 26 shows an example in which a tag is made by laminating double-faced adhesive tape or the like to the back surface of the IC inlet 1, and the tag is laminated to a front surface of an item, such as a ticket 34 or the like. The IC inlet 1 may be embedded in a single form into the inside of the item and can be used as a tag.

According to the above-mentioned embodiments of the present invention, a series of steps from the fabrication of the IC inlet to the inspection and the shipping of the IC inlets 1 can be performed continuously in a state in which a large number of the IC inlets 1 are formed on the insulating film 2, and, hence, the manufacturing cost of the IC inlet 1 can be reduced.

### Embodiment 2

Although an explanation has been given with respect to a method of inspecting a large number of IC inlets 1 that have been formed on the insulating film 2 one after another, it is possible to inspect a plurality of IC inlets 1 simultaneously.

FIG. 27 is a plan view showing a portion of the insulating film 2 used in this embodiment. On the insulating film 2, a large number of IC inlets 1 are arranged in two rows along the feeding direction (the left-and-right direction in the drawing) of the insulating film 2. These IC inlets 1 include antennas 3 having substantially one-half the length compared to the IC inlets 1 of the above-mentioned embodiment 1.

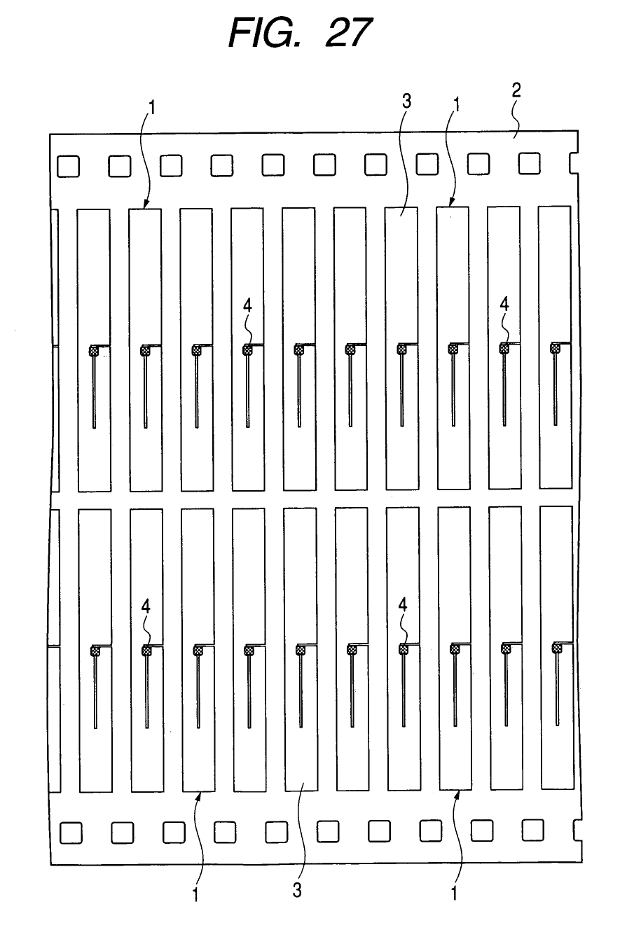

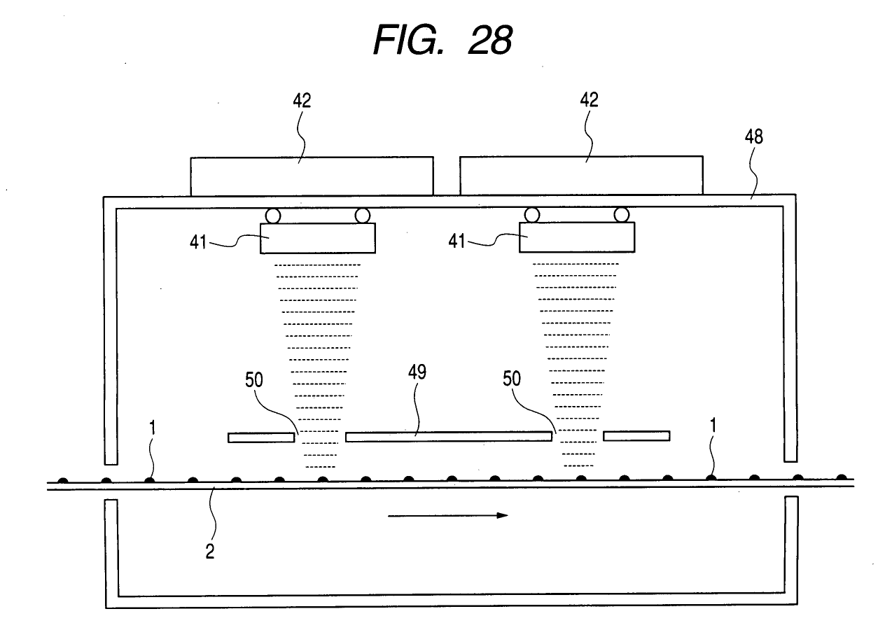

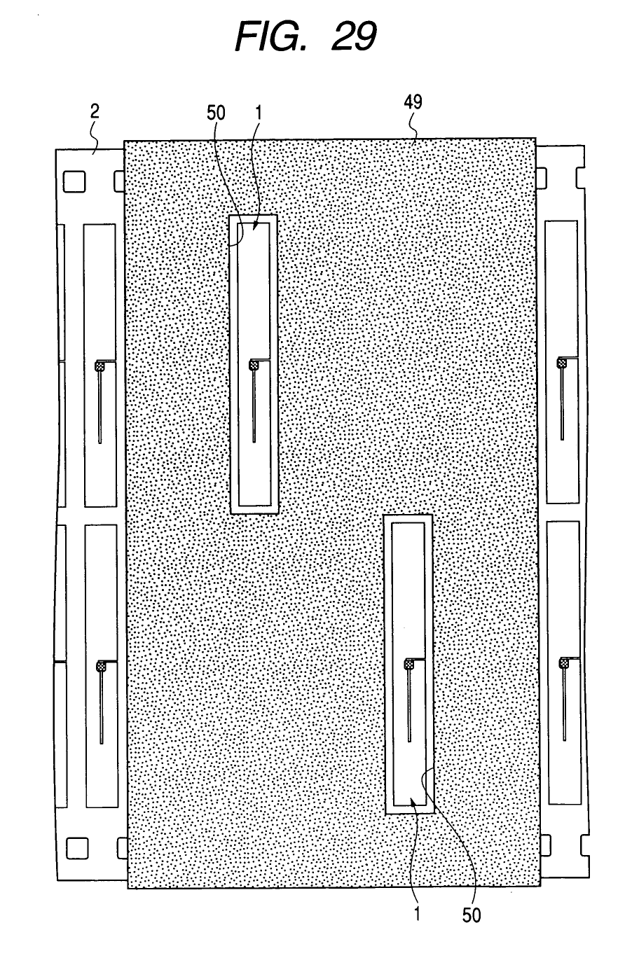

FIG. 28 is an example of an apparatus for simultaneously inspecting two IC inlets 1 out of a large number of IC inlets 1 formed on the insulating film 2. On a black box 48 of the apparatus shown in the drawing, two reader apparatuses 42 are mounted, while two antennas 41, which are connected to respective reader apparatuses 42, are mounted inside of the black box 48 in a spaced apart manner with a predetermined distance therebetween. Further, between the insulating film 2, which is fed to the inside of the black box 48, and the antennas 41, a radio-wave absorbing plate 49 is inserted. As shown in FIG. 29, in the radio-wave absorbing plate 49, two slits 50 having a size substantially equal to the size of one antenna 3 of the IC inlet 1 are formed.

Using such an inspection apparatus, the microwaves transmitted from one antenna 41 of two reader apparatuses 42 mounted in the black box 48 are irradiated to the IC inlet 1 of one row through one slit 50 of the radio-wave absorbing plate 49, while the microwaves transmitted from another antenna 41 of the two reader apparatuses 42 are irradiated to the IC inlet 1 of another row through another slit 50, and, hence, it is possible to simultaneously inspect two IC inlets 1. Here, when two slits 50 which are formed in the radio-wave absorbing plate 49 are set close to each other, there is the possibility that a microwaves transmitted from the two antennas 41 will interfere with each other, and, hence, it is desirable to set the distance between the two slits 50 sufficiently wide that they are spaced apart from each other to prevent such interference.

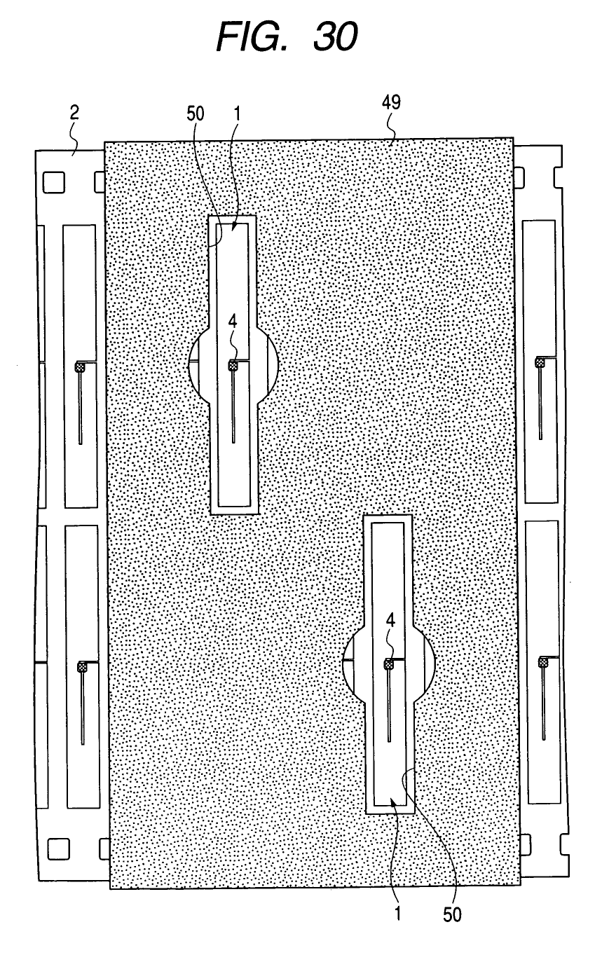

Further, as shown in FIG. 30, in forming the slits 50 in the radio-wave absorbing plate 49, by increasing the width of a center portion of each slit 50 more than the other portion of the slit 50, the strength of the microwaves irradiated to the center portion (a region where the semiconductor chip 5 is mounted) of the IC inlet 1 is increased, and, hence, the inspection accuracy is enhanced. In this case, although the microwaves are irradiated to a portion of the IC inlet 1 that is disposed close to the IC inlet 1, which is an object to be inspected, the strength of the microwaves irradiated to the neighboring IC inlet 1 is extremely weak, and, hence, the influence of the interference can be ignored.

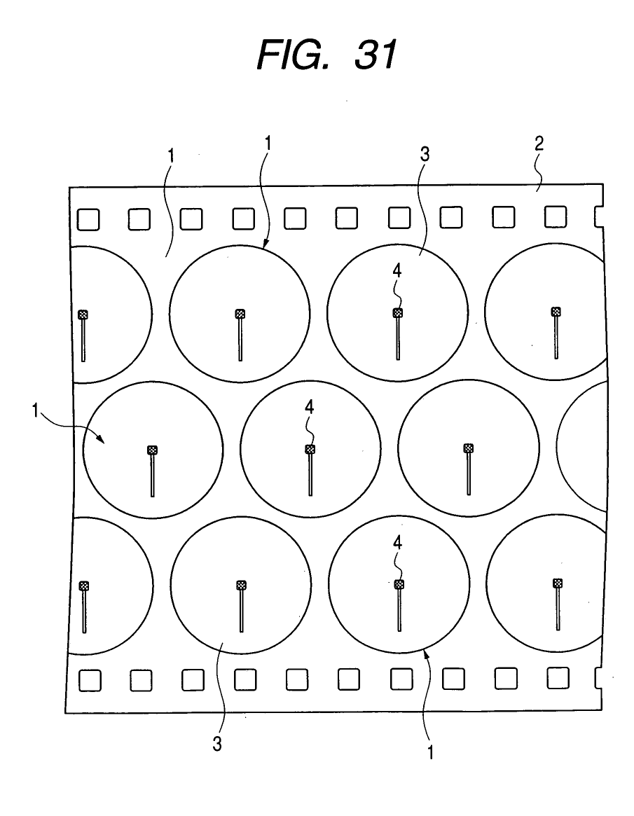

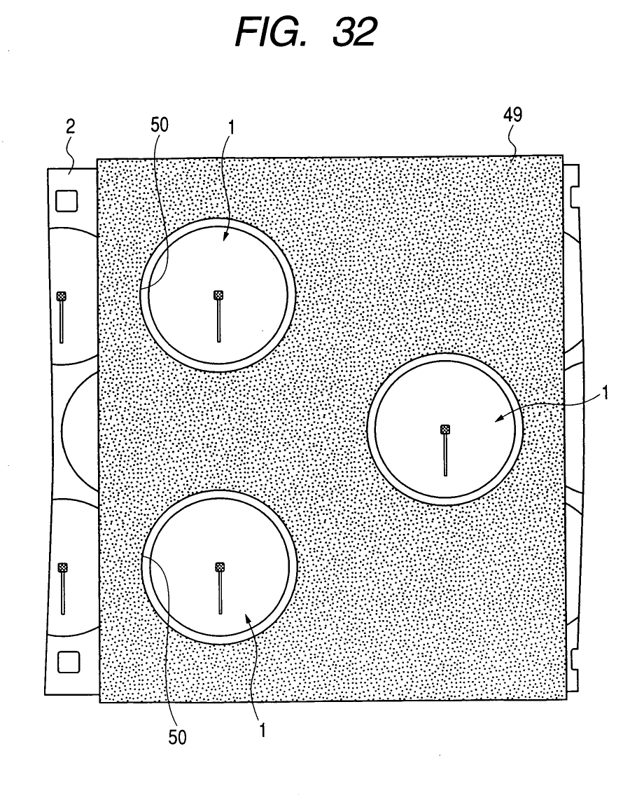

FIG. 31 shows an example in which the IC inlets 1, each having a circular antenna 3, are arranged in three rows along the feeding direction (left-and-right direction in the drawing) of the insulating film 2. In this case, as shown in FIG. 32, three slits 50, each having a size substantially equal to the antenna 3, are formed in the radio-wave absorbing plate 49, and three reader apparatuses 42 are stored in the black box 48 shown in FIG. 28, whereby three IC inlets 1 can be simultaneously inspected.

In this manner, by simultaneously inspecting a plurality of IC inlets 1 formed on the insulating film 2, the throughput of the inspection step can be enhanced, and, hence, the manufacturing cost of the IC inlet 1 can be further reduced.

### Embodiment 3

The IC inlet 1 of the embodiments 1, 2 uses a semiconductor chip 5 having an extremely small size in which the longitudinal size×lateral size=0.4 mm×0.4 mm, and, hence, by reducing the size of the antenna 3, it is possible to achieve an advantage in that an ultra small IC inlet can be realized.

However, when the profile size of the IC inlet is decreased, in the inspection method of the embodiment 1, the strength of the microwaves which reach the IC inlet 1 from the reader apparatus 42 through the slit 50 formed in the radio-wave absorbing plate 49, or the reflection wave, becomes extremely weak, and, hence, even when microwaves having a high directivity, such as a dipole, for example, are used, the inspection accuracy is lowered.

This embodiment is directed to a method which can perform an inspection with high accuracy even when the IC inlet 1 has an antenna 3 whose profile size is extremely small.

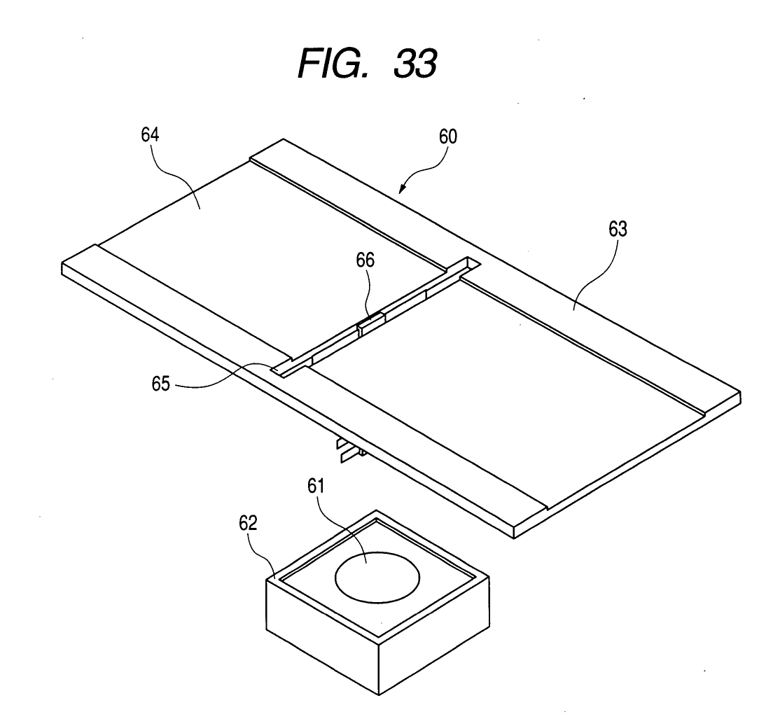

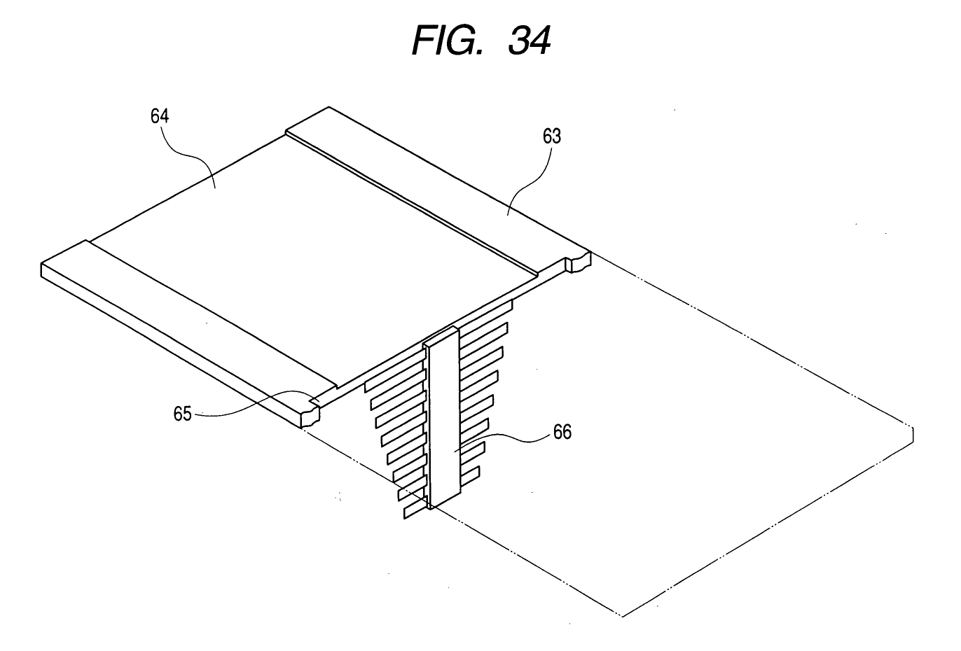

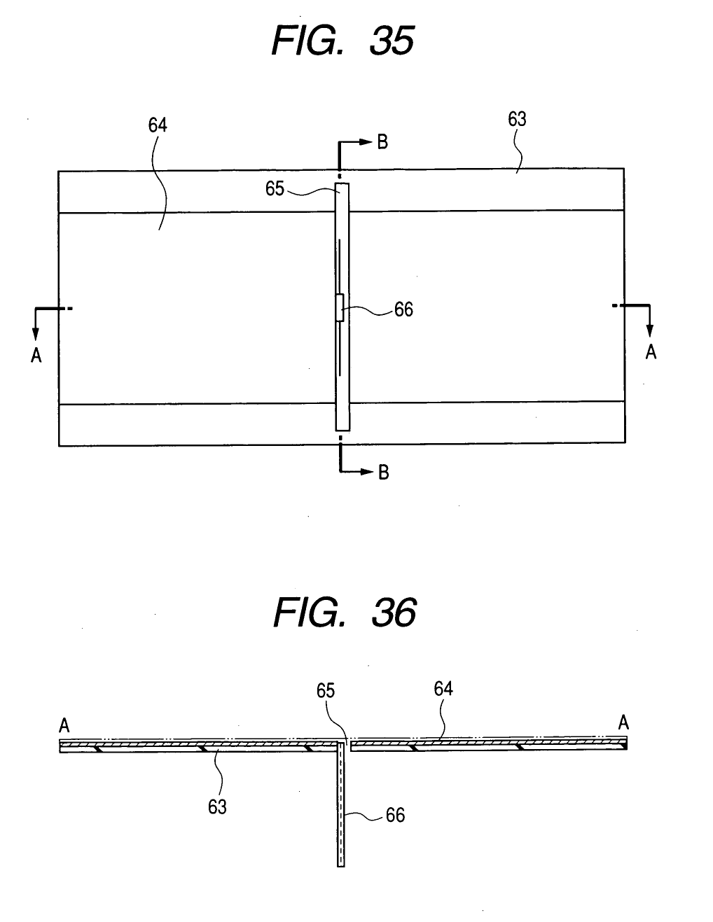

FIG. 33 is a perspective view showing part of an inspection apparatus according to this embodiment, FIG. 34 is a perspective view showing a portion of a guide rail of the inspection apparatus, FIG. 35 is a plan view of the guide rail as viewed from above, FIG. 36 is a cross-sectional view of the guide rail taken along a line A-A in FIG. 35, and FIG. 37 is a cross-sectional view of the guide rail taken along a line B-B in FIG. 35.

The inspection apparatus 60 is configured such that a guide rail 63 for positioning the insulating film 2 is arranged above the reader apparatuses 62 provided with an antenna 61 for reading. To a surface of the guide rail 63, a conductive plate 64 is laminated for absorbing microwaves, which plate has a function similar to the function of the radio-wave absorbing plate 49 of the embodiment 1. The conductive plate 64 is formed of a thin metal plate made of iron, stainless steel, copper, aluminum or the like, for example.

At an approximately center portion of the guide rail 63, a slit 65, is formed, having an opening size substantially equal to the profile size of the IC inlet 1, which becomes an object to be inspected. Further, a wave director 66, which functions as an antenna for amplifying the microwaves transmitted from the reader apparatus 62, is arranged below the slit 65.

As shown in FIG. 37, the wave director 66 is arranged in the direction perpendicular or vertical to an upper surface of the guide rail 63 and is fixed to the guide rail 63 in such a way that the wave director 66 has an upper end portion thereof adhered to or fitted into an inner wall of a slit 65. The wave director 66 has a structure in which the antennas 66a, which are formed of a plurality of thin metal plates, have gradually decreasing lengths downwardly (closer to the leader apparatus 62) from the upper end portion thereof at a fixed interval, and the plurality of antennas 66a are fixed to the support plate 66b.

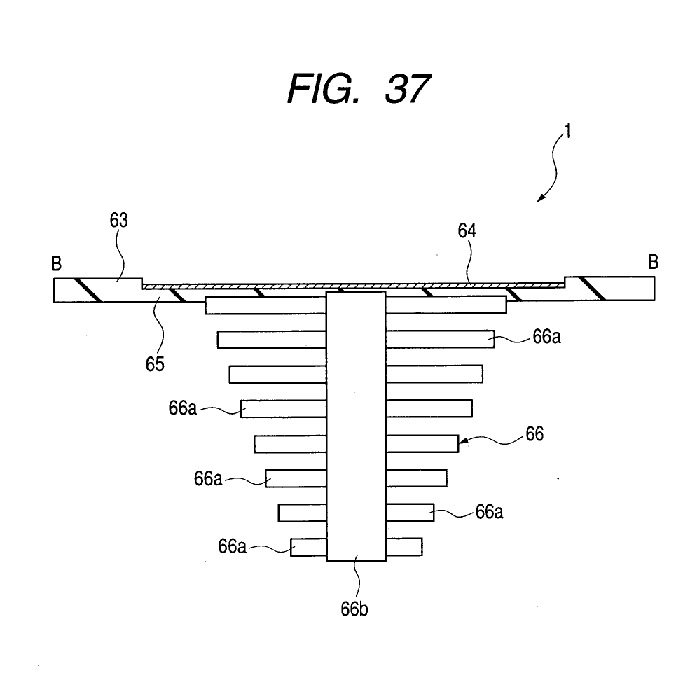

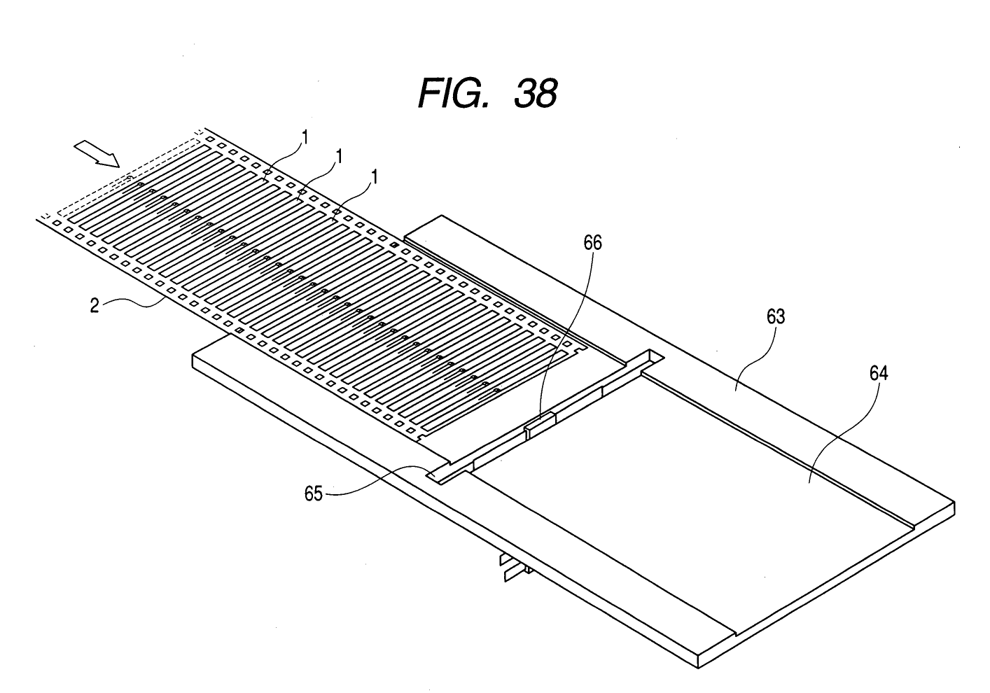

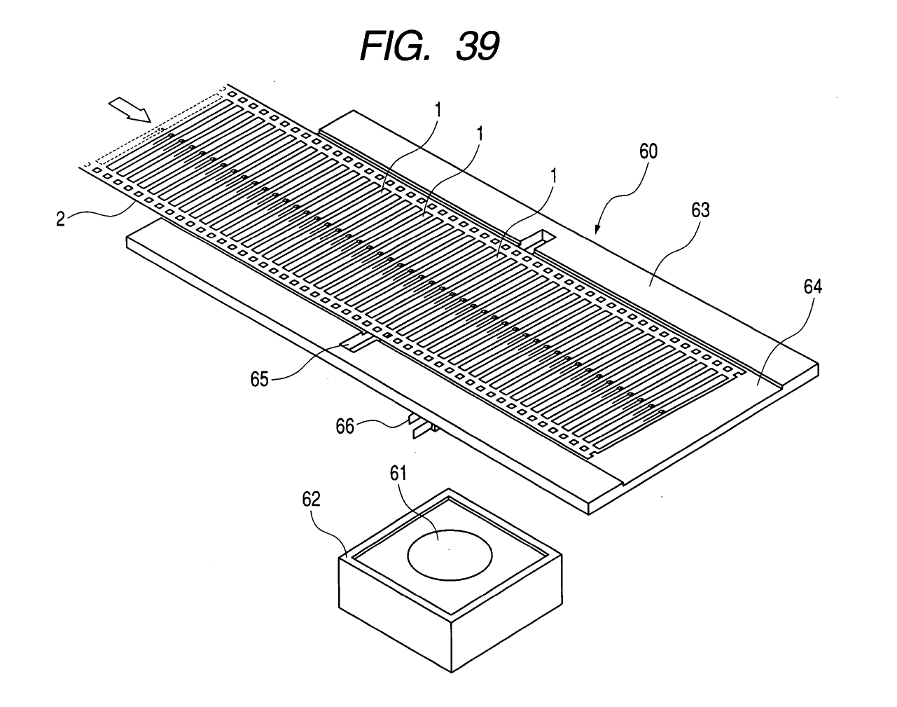

To perform the inspection of the IC inlet 1 using the above-mentioned inspection apparatus 60, as shown in FIG. 38, the insulating film 2, on which a large number of IC inlets 1 are arranged at a predetermined interval, is positioned on the upper surface of the guide rail 63 and is moved from one end to the other end of the guide rail 63. Then, as shown in FIG. 39, the microwaves are transmitted to the IC inlets 1 on the insulating film 2 through the antenna 61 of the reader apparatus 62 that is arranged below the guide rail 63.

Due to such an operation, below the slit 65 formed in the guide rail 63, the microwaves transmitted from the reader apparatus 62 reach the slit 65 while being amplified by the wave director 66, and, hence, the microwaves having high strength are irradiated to the IC inlet 1 to be inspected, which is positioned right above the slit 65 in a concentrated manner. To irradiate the microwaves having high strength to the IC inlet 1 to be inspected, it is desirable to make the distance between the IC inlet 1 and the upper end portion of the wave director 66 as small as possible. To the contrary, the larger the distance between both parts, the more the strength of the microwaves irradiated to the IC inlet 1 will be lowered.

According to the above-mentioned inspection method, even when the profile size of the IC inlet 1 is extremely small and, hence, the opening size of the slit 65 corresponding to the IC inlet 1 is extremely small, it is possible to selectively irradiate microwaves having a high strength to the IC inlet 1 to be inspected. Accordingly, it is possible to accurately read the ROM data written in the IC inlet 1 to be inspected, whereby it is possible to determine with high accuracy whether the IC inlets 1 formed on the insulating film 2 are non-defective or defective.

Although the inspection apparatus 60 can perform the inspection operation in a state in which the guide rail 63 and the reader apparatus 62 are housed in the black box 48, it is possible to perform the inspection with high accuracy even when the black box 48 is not used.

Further, it is needless to say that the inspection apparatus 60 of this embodiment is also applicable to the inspection of IC inlets 1 having a relatively large profile size. Also in this case, compared to the inspection apparatus 40 of the embodiment 1, which does not use the wave director 66, it is possible to perform the inspection by separating the IC inlet 1 to be inspected and the reader apparatus, such that the distance is approximately two or three times longer than the distance of the embodiment 1.

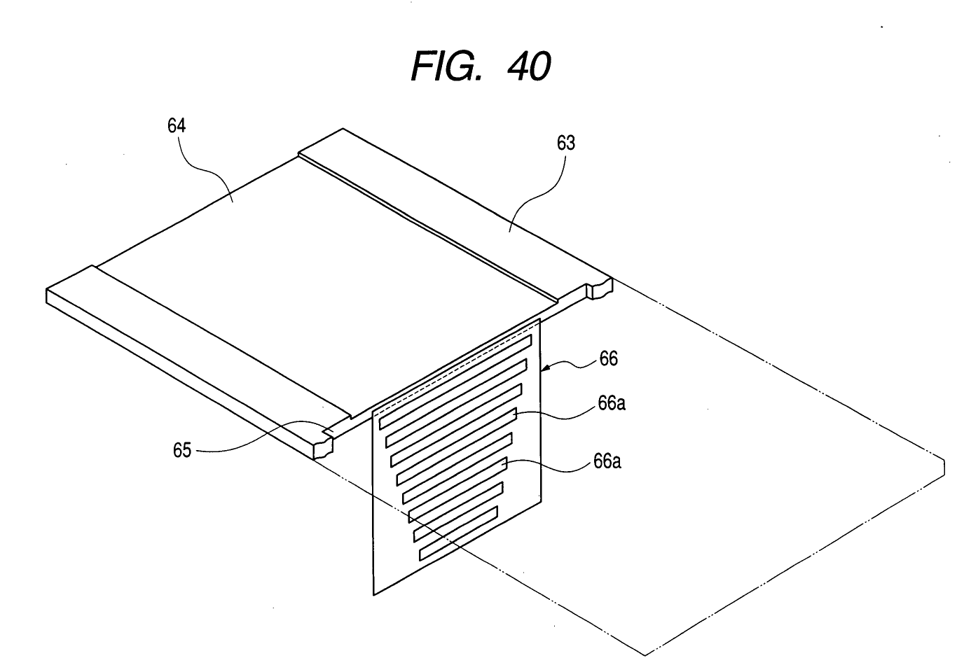

Here, with respect to the wave director 66 mounted on the guide rail 63, in response to the profile of the IC inlet 1 to be inspected, the shape and the number of the antennas 66a and the distance between the antennas 66a are optimized. Accordingly, the wave director 66 is not limited to the above-mentioned structure. For example, as shown in FIG. 40, the wave director 66 may be formed by laminating antennas 66a formed of metal plates to a surface of a thin paper or resin film. The metal plates which constitute the antennas 66a can be fabricated by various methods, such as pressing, printing, etching and the like. Further, in place of the metal plates, the antennas 66a may be formed using wires made of a conductive material or fiber threads.

### Embodiment 4

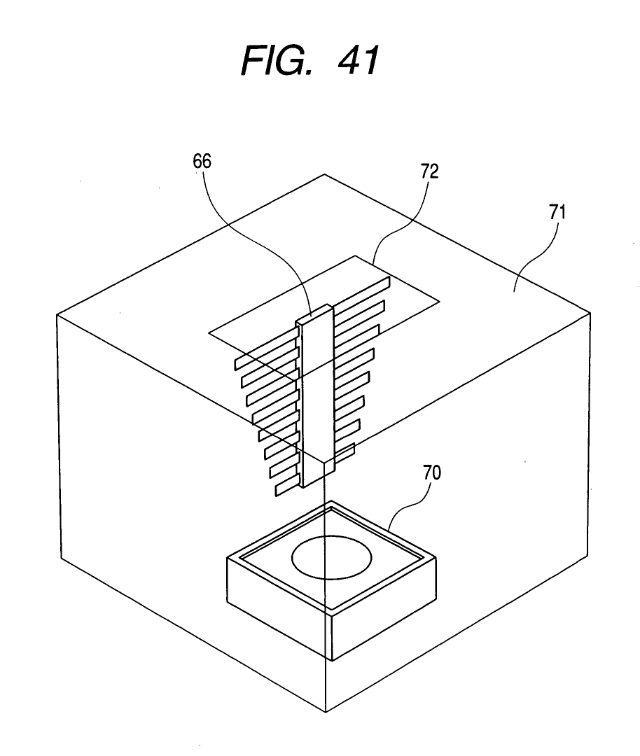

FIG. 41 is a schematic constitutional view of an ID tag reader 70 which reads ROM data of an ID (identification) tag having the IC inlet 1 of the previous embodiment 1 mounted thereon.

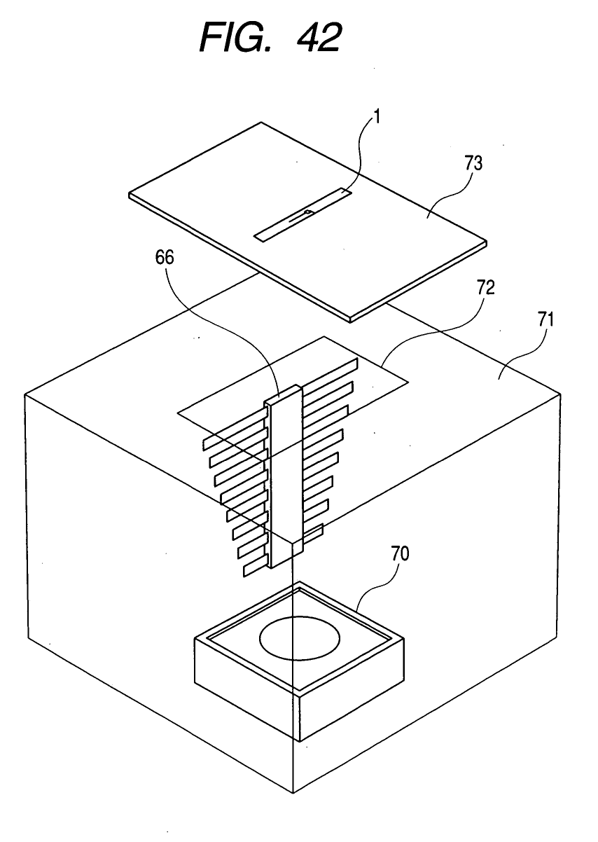

Below and in the vicinity of a measuring portion 72 which is formed on an upper surface of a box 71 in which the ID tag reader 70 is housed, the wave director 66, which has been described in conjunction with the previous embodiment 3, is mounted. As shown in FIG. 42, in reading the ROM data of the IC inlet 1 mounted on an ID tag 73, for example, the ID tag 73 is brought close to the measuring portion 72. In this case, when the wave director 66 is mounted below and in the vicinity of the measuring portion 72, the microwaves transmitted from the ID tag reader 70 are amplified by the wave director 66; and, hence, even when irregularities are generated due to the distance from the measuring portion 72 to the ID tag 73 or the inclination of the ID tag 73, an accurate reading can be realized, whereby the reading operation of the ROM data can be performed rapidly and accurately.

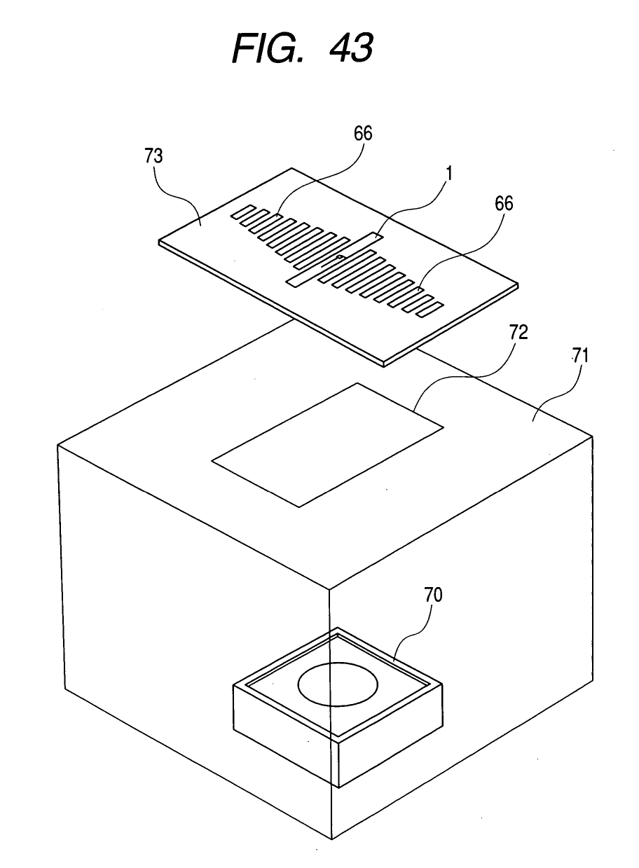

Further, as shown in FIG. 43, in place of mounting the wave director 66 to the ID tag reader 70 side, the wave director 66 may be mounted on the ID tag 73 side. Also in this case, even when irregularities are generated due to the distance from the measuring portion 72 to the ID tag 73 or the inclination of the ID tag 73, an accurate reading can be realized.

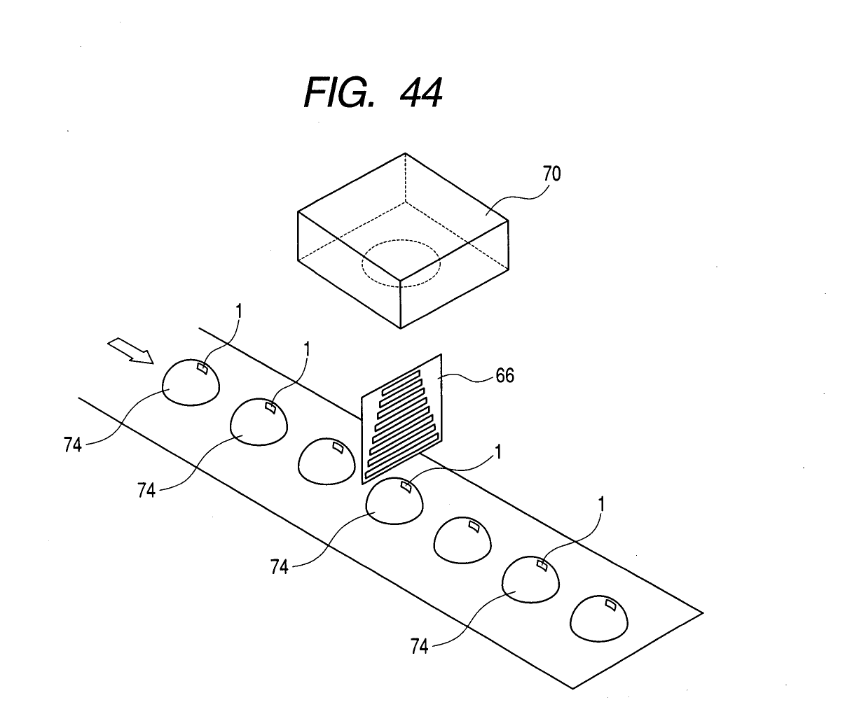

FIG. 44 shows an example of a method of sequentially reading ROM data of IC inlets 1, which are laminated to surfaces of a large number of articles 74, which are continuously transported. Also in this case, by arranging the wave director 66 in the vicinity of one article 74 to be read, the microwaves which are transmitted from the reader apparatus 70 are amplified by the wave director 66, and, hence, even when the shape of the article 74 is spherical or an irregular shape having projections and recesses, it is possible to rapidly and accurately perform the reading of the ROM data.

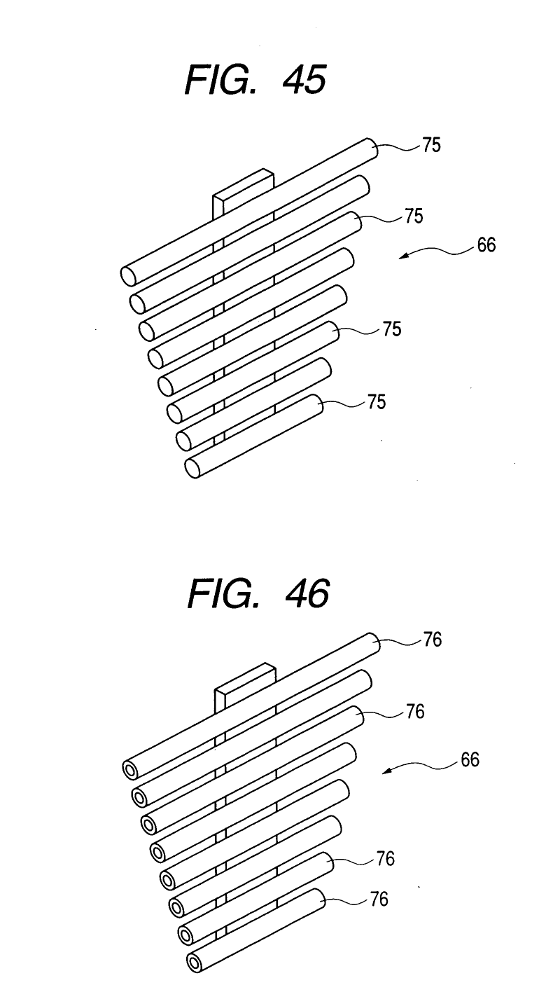

Further, as shown in FIG. 45 and FIG. 46, the antennas of the wave director 66 may be formed of metal rods 75 having a circular cross section or metal hollow pipes 76, and these rods 75 or the hollow pipes 76 are used in a state in which they are embedded in the inside of an article together with the IC inlet 1.

Although the invention made by the inventors has been specifically described based on the foregoing embodiments, it is needless to say that the present is not limited to the above-mentioned embodiments and that various modifications thereof can be made without departing from the gist of the present invention.

In the IC inlet of the embodiment 1, the antenna 3 is constituted of a Cu foil laminated to an insulating film 2 that is made of polyimide resin. However, for example, by constituting the antenna 3 using an Al (aluminum) foil laminated to one surface of the insulating film 2, or by constituting the resin film 2 using resin (for example, polyethylene terephthalate) which is cheaper than polyimide resin, it is possible to reduce the fabrication cost of the IC inlet 1. When the antenna 3 is constituted of Al foil, it is preferable to perform the connection between the Au bumps (9a to 9d) of the semiconductor chip 5 and the antenna 3 by Au/Al bonding, which uses ultrasonic waves and heating in combination.

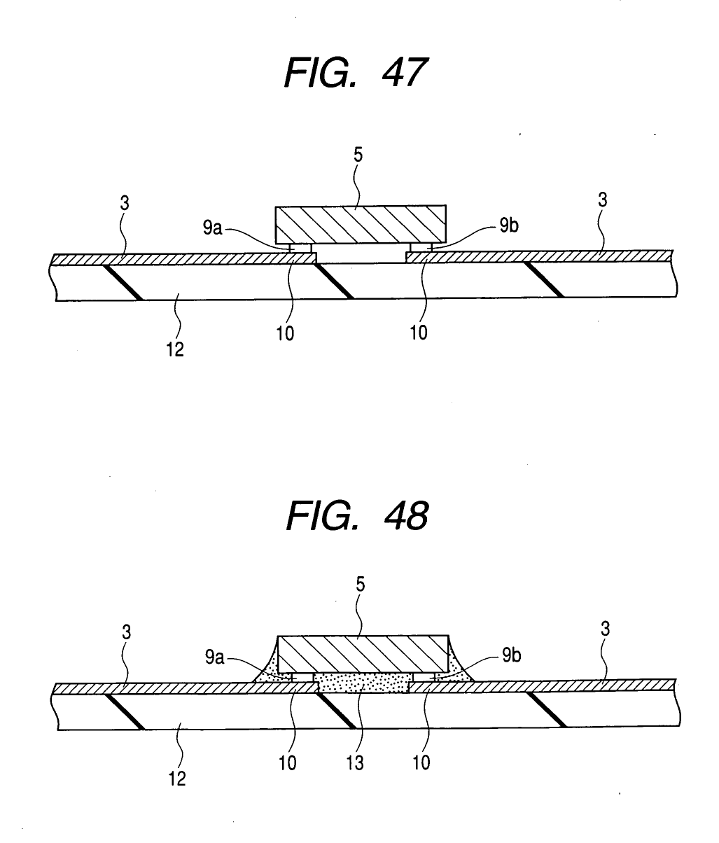

Although an explanation has been made with respect to an IC inlet having a TCP (Tape Carrier Package) structure in the above-mentioned embodiments 1 to 3, for example, as shown in FIG. 47, it may be possible to adopt a COF (Chip On Film) structure, which integrally forms the antenna 3 and the leads 10 on one surface of an insulating film 12 having no device hole 8 and connects the terminals (Au bumps 9a, 9b) of the semiconductor chip 5 to the leads 10. In this case, after connecting the leads 10 and the terminals (Au bumps 9a, 9b), as shown in FIG. 48, an underfill resin 13 is filled in a gap defined between the leads 10 and the terminals (Au bumps 9a, 9b).

The IC inlet having the COF structure shown in FIG. 47 can surely perform the connection between leads 10 and the terminals (Au bumps 9a, 9b) compared to the IC inlet having the TCP structure, and, hence, the reliability of the connection of both elements is high, whereby it is possible to omit the dummy bumps (9c, 9d). However, since the connecting portions between the leads 10 and the terminals (Au bumps 9a, 9b) cannot be observed by the human eye from the back surface side of the insulating film 12, the method of inspecting the appearance requires some modification. Further, some modification is required for surely filling the underfill resin 13 into an extremely narrow gap defined between the leads 10 and the terminals (Au bumps 9a, 9b).

Further, it is also possible to apply the present invention to an IC inlet in which the antennas are formed using a lead frame and a semiconductor chip, and the antennas are connected by bonding wires as in the case of the IC inlets described in Japanese Patent Application 2001-300841 and Japanese Patent Application 2002-209601, filed by the present inventors et al. In this case, since a plurality of antennas are connected to each other by a frame body of the lead frame, first of all, the lead frame is laminated to an insulating film, and, thereafter, the frame body of the lead frame is cut so as to separate the antennas. Thereafter, the inspection may be performed in accordance with the method described in conjunction with the above-mentioned embodiments.

A brief explanation of the advantageous effects obtained by the invention disclosed in this specification follows.

By selectively irradiating the microwaves to only the IC inlet to be inspected, out of a large number of IC inlets formed on the insulating film, it is possible to effectively inspect the IC inlets without separating them into individual pieces.

Further, by providing a wave director which functions as an antenna which amplifies the microwaves in the vicinity of the IC inlet to be inspected, the inspection accuracy can be enhanced.

1. A fabrication method of IC inlets comprising the steps of:
(a) separating a plurality of semiconductor chips including memory circuits in which predetermined data is written into individual pieces from a semiconductor wafer;
(b) preparing an insulating film formed in a state that a plurality of antennas which receive radio waves of a predetermined frequency are separated from each other;
(c) connecting the semiconductor chips to the plurality of respective antennas formed over the insulating film;
(d) forming a plurality of IC inlets over the insulating film by sealing the plurality of respective semiconductor chips after the step (c); and
(e) inspecting whether the plurality of IC inlets are non-defective or defective by selectively irradiating radio waves of the predetermined frequency to the plurality of respective IC inlets formed over the insulating film.

2. A fabrication method of IC inlets according to claim 1, wherein in steps prior to the step of separating the plurality of semiconductor chips into individual pieces from the semiconductor wafer, inspecting whether the plurality of semiconductor chips are non-defective or defective is not performed.

3. A fabrication method of IC inlets according to claim 1, wherein the radio waves irradiated to the IC inlet in the step (e) is linear polarized waves or dipole.

4. A fabrication method of IC inlets according to claim 1, wherein at the time of irradiating the radio waves to the IC inlet in the step (e), between radio-wave transmitting source and the IC inlet, a radio-wave absorbing body having a slit substantially equal to the IC inlet in size is interposed, and the radio waves are selectively irradiated to the IC inlet through the slit.

5. A fabrication method of IC inlets according to claim 1, wherein the method further includes, after the step (e), a step of shipping the plurality of IC inlets formed over the insulating film without separating the IC inlets into individual pieces.

6. A fabrication method of IC inlets according to claim 5, wherein non-defective and defective data of a plurality of IC inlets which are inspected in the step (e) are written in a storage medium and the storage medium is shipped together with the plurality of IC inlets formed over the insulating film.

7. A fabrication method of IC inlets according to claim 1, wherein at the time of irradiating the radio waves to the IC inlet to be inspected in the step (e), by bringing a conductor into contact with the antennas of the IC inlets other than the IC inlet to be inspected, the radio-wave reflection performance of the antennas is lowered.

8. A fabrication method of IC inlets according to claim 1, wherein the method further includes a step of removing the semiconductor chip from the IC inlet which is determined to be defective among the plurality of IC inlets inspected in the step (e).

9. A fabrication method of IC inlets according to claim 1, wherein the method further includes, after the step (d), a step of inspecting the appearance of the plurality of respective IC inlets formed over the insulating film.

10. A fabrication method of IC inlets according to claim 1, wherein the memory circuit which is formed over each one of the plurality of respective semiconductor chips is a ROM and the predetermined data written in the ROM includes identification data intrinsic to each one of the plurality of respective semiconductor chips.

11. A fabrication method of IC inlets according to claim 1, wherein the method further includes a step in which a mark is selectively formed over the IC inlets which are determined to be non-defective out of the plurality of the IC inlets inspected in the step (e).

12. A fabrication method of IC inlets according to claim 1, wherein the step (e) is performed on a fabrication line which includes the steps (a), (b), (c) and (d).

13. A fabrication method of IC inlets according to claim 1, wherein the step (e) is performed on a line different from a fabrication line which includes the steps (a), (b), (c) and (d).

14. A fabrication method of IC inlets according to claim 1, wherein at the time of inspecting whether the plurality of IC inlets are non-defective or defective in the step (e), the radio waves are simultaneously irradiated from a plurality of radio-wave transmitting source to a plurality of IC inlets to be inspected.

15. A fabrication method of IC inlets according to claim 14, wherein between the plurality of radio wave transmitting sources and the plurality of IC inlets to be inspected, a radio-wave absorbing body in which a plurality of slits having substantially the same size as the IC inlet are formed is interposed, and the radio waves are selectively irradiated to the plurality of respective IC inlets to be inspected through the plurality of respective slits.

16. A fabrication method of IC inlets according to claim 1, wherein the antennas are formed by patterning a copper foil or an aluminum foil which is formed over one surface of the insulating film, and the antennas and the semiconductor chip are connected to each other using either a tape carrier package method or a chip-on-film method.

17. A fabrication method of IC inlets according to claim 1, wherein the antennas and the semiconductor chip are connected to each other by means of wires which have one ends thereof bonded to the antennas and another ends bonded to terminals of the semiconductor chip.

18-28. (canceled)

29. An ID tag provided with an IC inlet in which a semiconductor chip including a memory circuit to which predetermined data is written is mounted to an antenna, wherein a wave director which amplifies radio waves for reading the data written in the semiconductor chip in a non-contact state is mounted in the vicinity of the IC inlet.

30. An ID tag according to claim 29, wherein the wave director is formed by arranging a plurality of conductors which function as antennas at a fixed interval.

31-33. (canceled)

34. A method of reading data using an ID tag reader, wherein by irradiating radio waves of a predetermined frequency to an ID tag provided with an IC inlet wherein a semiconductor chip including a memory circuit in which predetermined data is written is mounted to an antenna, at the time of reading the data written in the semiconductor chip in a non-contact manner, a wave director for amplifying the radio waves is mounted between an ID tag reader which is provided with a transmitting source of the radio waves and the ID tag.
